(19) United States
(12) Patent Application Publication
(10) Pub. No.: US 2024/0261909 A1
(43) Pub. Date: Aug. 8, 2024

(54) COLLABORATIVE ROBOT WELDING SYSTEM AND METHOD

(71) Applicant: Vectis Automation, LLC, Loveland, CO (US)

(72) Inventors: Andrew Akey, Windosr, CO (US); Joshua Pawley, Windsor, CO (US); Douglas Rhoda, Timnath, CO (US); Aaron Bailey, Fort Collins, CO (US)

(73) Assignee: Vectis Automation, LLC, Loveland, CO (US)

(21) Appl. No.: 18/641,396

(22) Filed: Apr. 21, 2024

Related U.S. Application Data
(62) Division of application No. 17/244,951, filed on Apr. 30, 2021.
(60) Provisional application No. 63/017,321, filed on Apr. 29, 2020.

(51) Int. Cl. B23K 37/02; B25J 5/00; B25J 9/00; B25J 9/16; B25J 11/00

(52) U.S. Cl. CPC B23K 37/0211; B23K 37/0294; B25J 5/00; B25J 9/0081; B25J 9/1666; B25J 11/005

(57) ABSTRACT

A collaborative robot welding system for the assembly, construction, fabrication, and/or the completion of weldments. A method of assembly and fabrication of weldments employing the intuitive graphical interactive programming features of a robot welding system user interface to enhance productivity and versatility in high mix, low volume weld fabrication environments with minimal operator training.

### CROSS-REFERENCE TO RELATED APPLICATIONS

This is a divisional patent application which claims priority to U.S. Provisional Patent Application Ser. No. 63/017,231 filed on Apr. 29, 2020, and to U.S. Utility patent application Ser. No. 17/244,951 filed on Apr. 29, 2021, the entire contents of which are incorporated herein by reference.

### FIELD OF THE INVENTION

The present invention relates generally to welding systems. More specifically, the present invention relates to robot welding systems, and in particular to robot welding cell units. In particular, the present invention relates to a readily re-deployable collaborative robot welding system adaptable for intuitive programming and operation by an operator without requiring specialized and extensive training and a method for fabricating a weldment therewith.

### BACKGROUND OF THE INVENTION

During the course of the last one hundred and twenty years, electric arc welding has evolved from the use of essentially a bare electrode employed to create molten metal by generating an electric arc between one end of the electrode and a workpiece to complex, highly-automated systems designed to fabricate complex structures from both ferrous and non-ferrous base metal alloys. The physical properties, chemical composition, sensitivity to oxidation and heat transfer characteristics of various alloys demand close attention to materials joining techniques used to create sound weldments in a wide variety of structures and products. Consumer awareness of the science, engineering and ingenuity involved in modern manufacturing is not widespread. Examples of welded structures extend at one end of the spectrum from commonplace household appliances, furniture, exercise and lawn maintenance equipment to expensive and sophisticated space and airborne platforms, military equipment, scientific apparatus, chemical processing systems and medical devices fabricated from exotic metals. The list is endless.

Welding engineering is a highly-specialized discipline which requires knowledge of not only structures, materials and manufacturing processes, but also knowledge of specific welding processes and associated parameters including weld joint configuration, arc length, wire feed rate, travel speed, welding power supply settings such as arc voltage and current, shielding gas composition, preheat and post heat requirements, weaving parameters and other variables. A knowledgeable welder may assess the requirements of a particular job based upon prior experience and may adjust one or more of the foregoing parameters to achieve the desired weld penetration and weld bead configuration from both a functional and an aesthetic perspective. However, a less experienced individual may not be able to set up a weld job without performing trial and error runs on test pieces, a process which is time consuming, inefficient, and costly.

Optimal weld quality depends not only on proper welding parameter settings, but also on physical consistency of the path and angle of the weld torch, intangibles which may be influenced by an individual welder's skills; variable situational influences including concentration, fatigue, and health issues; and operating environment factors such as heat, humidity, lighting and ventilation. These factors are particularly influential on weld quality where the welding process is performed with a hand-held electrode or torch.

Automated welding systems have been developed to enhance weld quality, consistency, and productivity by minimizing adverse effects of variable welding process parameter input and human performance. Automated systems typically replace the historical hand-held and guided coated or “stick” electrode process with automated continuous wire feed systems such as Gas Metal Arc Welding (GMAW), flux-cored arc welding (FCAW), gas tungsten arc welding (GTAW) or submerged arc welding (SAW) systems. The afore-mentioned automated processes may be used in connection with work-holding fixtures, weld head positioners and robot systems that can be programmed for specific welding applications. Nonetheless, if an operator enters incorrect parameter settings or fails to notice technical process irregularities during the course of fabricating a weldment, inevitably, scrap and rework will be the result. Even more serious is the possibility of catastrophic field failure of a welded structure, for example a bridge truss or an airframe, both of which may result in personal injury or loss of life.

Previous attempts to minimize welding parameter selection and input errors include the use of pre-prepared tables or mathematical equations to aid a welder in calculating setup parameters. Advances in process control technology include the integration of a graphical user interface into a welding power supply control system, such as disclosed in U.S. Pat. No. 7,781,700 issued to James A. Harris, Aug. 10, 2010. The Harris' interface provides a dynamic graphical display of the welding parameter settings and representative changes to a weld bead profile that would occur in response to changes in welding process parameters.

More recently, U.S. patent Application Publication No. US 2018/0095640 published Apr. 5, 2018, by Albright et al., discloses a robot arc welding system that includes a user interface and display system having a processor which receives and analyzes the welding power supply parameter settings in real time during a welding cycle. The display is configured to send a pictograph warning graphically to the system operator in response to the detection of maladjustment in a parameter setting. While both the Harris and Albright et al. control systems have been important contributions to the welding industry, these and other prior art systems require complex off-site programming and operator training to properly set up and operate the systems. These systems are further limited by high capital acquisition costs and limited versatility for use across multiple and diverse applications.

As noted above, automated robot and positioning systems controlled by computer software programs have displaced manual weld fabrication operations in many industries. Analogous to CAD/CAM machine tool equipment, automatic robot welding systems are designed to minimize or completely eliminate the variables associated with manual welding operations, reduce the tedium associated with repetitive tasks, and enhance productivity and efficiency. In addition to the foregoing, typically, automated welding systems include a work holding table or positioner and a device such as an extendable boom or a robot arm which holds the welding implement such as a torch or electrode. Either or both of these positioning and implement holding devices may be programmed to rotate about or translate along one or more axes to define a welding path and may include multiple workstations which permit welding fabrication of an assembly at one station while an operator removes a completed assembly and sets up a new work piece at a different station. Known in the art as welding cells, exemplary prior art systems include a robot welding cell unit disclosed in U.S. Pat. No. 7,238,916 B2 issued to Samodell et al., Jul. 3, 2007, and a robot cell disclosed by Osicki in United States patent Application Publication No. US 2010/0072184 A1 published on Mar. 25, 2010.

Depending upon the application, automated robot welding systems can be massive assemblies requiring substantial acquisition and installation capital expenditures, dedicated floor space, safety systems, utility inputs for electrical power, hydraulics and/or cooling water; and overhead cranes or lateral material conveyance systems for work material and finished assembly transport. Although the system disclosed by Samodell et al. is designed for smaller manufacturing operations and may be moved from one location to another via forklift and pickup truck, the welding cell is not amenable for use with different welding systems (GMAW, GTAW, SAW, for example), high mix, low volume production, or movement within a manufacturing facility without potentially disrupting other operations.

Welding is so precise and the risks of property loss and/or personal injury to users of the welded structures so pervasive in modern society that the setup and identification of the input variables in both manual and computer-controlled robot weld fabrication operations, as well as the execution of the welding process applicable to a given application, require manual input, a process that draws upon the skills and experience of the individual welder performing the task. However, a severe lack of welders in today's workforce presents yet another challenge to meeting the demands of a highly consumptive economy. The American Welding Society estimates the average age of a welder to be 54 years old. The number of active welders is decreasing at a rate that is significantly higher than the entry rate of new welders into the field, and a potential shortage of approximately 400,000 welders in the United States is project to exist by 2025. The situation is further exacerbated by socio-economic societal changes brought about by the expectations and demands of younger generations for higher paying jobs in what are viewed as the “high tech” fields of computer science, programming, communications and information technology and the like. Traditional jobs in manufacturing, agriculture, foundries and mining are now viewed as less desirable or have migrated off-shore.

Consequently, manufacturers are under tremendous stress to increase welding productivity through automation but currently have only risky and costly options to do so. Traditional robot welding solutions are a significant financial risk, bulky and expensive, with long delivery times, significant set-up time and cost, and what operations managers view as “well, no-turning-back now” risk. While larger corporations may be able to bear the cost and risk of traditional automation, the smaller shops that make up 75% of America's 250,000+ manufacturers are prohibited by the high capital investment requirements from availing themselves of the advantages offered by either partially or fully automated systems.

In view of the above, it is evident on the one hand that demands in the welding industry for reliable, consistent and repeatable welded structure fabrication processes may be satisfied by sophisticated and very costly automated systems that minimize the potentially adverse and unpredictable effects of human and process variables on weld quality. However, conflicting demands for relatively inexpensive, mobile and versatile welding systems capable of producing weldments of the highest quality that may also be set up and operated by less experienced individuals in high mix, low volume production environments create a tension in the industry that heretofore has not been addressed by prior art systems. Accordingly, it will be apparent to those skilled in the art from this disclosure that a need exists for a collaborative robot welding system that can be set up and programmed intuitively by an operator without the need for significant computer programming and coding training. A need also exists for a readily re-deployable and transportable automated welding system that may be installed in a manufacturing operation and moved from one worksite to another without significant labor or rigging or substantial acquisition and installation capital expenditures, dedicated floor space, or ancillary internal support and operating systems The present invention addresses aforementioned needs in the art as well as other needs, all of which will become apparent to those skilled in the art from the accompanying disclosure.

### SUMMARY OF THE INVENTION

In accordance with the embodiments of the present invention, a collaborative robot welding system is disclosed for performing welding tasks related to the initial assembly, construction, fabrication and/or completion of weldments, including tack welding together components of a weldment, performing the welding tasks associated with a given weldment, and/or completing a partially finished welding project.

In an embodiment, the collaborative robot welding system contains a control system which enables an operator or a programmer to guide the robot to a preselected position in a weld path by hand.

In another embodiment the collaborative robot welding system includes a user interface or a teach pendant adapted to allow programming to be completed in an intuitive and graphical manner without requiring significant and specific education, training or computer programming and coding experience or skills.

In yet another embodiment, a highly-mobile collaborative robot welding system includes a mobile base having a gridded worksurface, the mobile base being adapted to be relocated without significant labor and/or rigging to bring the welding system to the work.

In still another embodiment, a highly-mobile collaborative robot welding system includes a collaborative robot welding arm, a mobile base including a bottom or lower platform adapted to stow and transport welding system accessory equipment, and an upper cantilevered shelf adapted to mount the collaborative robot welding arm, the mobile base being adapted to be relocated without significant labor and/or rigging to bring the welding system to the work.

In another embodiment, a highly-mobile collaborative robot welding system includes a collaborative robot welding arm, an extended mobile base including a bottom or lower platform adapted to stow and transport welding system accessory equipment, and an upper cantilevered shelf adapted to mount the collaborative robot welding arm, the extended mobile base being adapted to be relocated without significant labor and/or rigging to bring the welding system to the work.

In yet another embodiment, a highly-mobile collaborative robot welding system includes an extended mobile base, the extended mobile base being adapted to be relocated without significant labor and/or rigging to bring the welding system to the work.

In still another embodiment, a collaborative robot welding system includes a programmable robot arm having a preselected reach distance, the programmable robot arm being adapted to hold a welding implement.

In another embodiment, the collaborative robot welding system and mobile base are adapted to be positioned adjacent separate preexisting fixtures within the reach distance of the programmable welding arm, whereby welding operations are performed on materials on the adjacent separate fixtures.

In yet another embodiment, a collaborative robot welding system includes a programmable robot arm having a magnetic base.

In still another embodiment, a collaborative robot welding system and mobile base are adapted to weld large stationary structures in indoor manufacturing and field service environments.

In another embodiment, the programmable collaborative robot arm includes a built-in safety in the robot arm itself.

In another embodiment, the collaborative robot welding system and mobile base include a safety system which permits the collaborative welding system to be operated at a faster speed under predetermined conditions which are safe for an operator and which reduces the system operating speed in accordance with recognized safety standards in response to conditions detected by the safety system.

In still another embodiment, the collaborative robot welding system includes a corner-mounted operator protection safety system mounted in a mobile base.

In yet another embodiment, a collaborative robot welding system provides increased operator safety by placing the operator at a position removed from the site of welding fume generation, assisting with, or eliminating potentially fatiguing and injurious repetitive lifting procedures and out-of-position tasks.

In another embodiment, a collaborative robot welding system provides enhanced production efficiency by allowing an operator to set up and complete more tasks through parallel and simultaneously performed operational steps and by shifting repetitive, monotonous welding tasks to the collaborative robot welding system.

In yet another embodiment a collaborative welding system includes a stationary base or worktable adapted for use in the fabrication of large, welded assemblies.

In an embodiment, a collaborative welding system includes a gridded worktable adapted to receive and secure work material and work holding fixtures thereto.

In another embodiment a collaborative welding system includes a worktable have a plurality of magnetic robot arm docking stations secured thereto, each of the plurality of docking stations being selectively positionable on the worktable in response to the size, configuration and number of welded assemblies to be processed.

In yet another embodiment, a collaborative robot welding system includes a boom assembly adapted to selectively move and position one or more programmable collaborative robot arms on a worktable in response to the size, configuration and number of welded assemblies to be processed.

In still another embodiment, a method for fabrication a weldment using a collaborative robot welding system is disclosed in accordance with the present invention.

In an embodiment, a collaborative robot cutting system is disclosed for performing cutting tasks related to cutting materials of various shapes and thicknesses.

These and other features, aspects and advantages of the present invention will become apparent to those skilled in the art from the following detailed description of preferred embodiments taken in connection with the accompanying drawings, which are summarized briefly below.

### BRIEF DESCRIPTION OF THE DRAWINGS

Referring now to the attached drawings which form a part of this original disclosure:

FIG. 1 is a front top perspective view of the elements of a collaborative robot welding system having a mobile base in accordance with an embodiment of the present invention;

FIG. 2 is a rear top perspective view of the collaborative robot welding system of FIG. 1 in accordance with an embodiment of the present invention;

FIG. 3 is a perspective view of a collaborative robot arm assembly and welding implement of the collaborative robot welding system of FIGS. 1 and 2 in accordance with an embodiment of the present invention;

FIG. 4 is a front perspective view of the elements of a collaborative robot welding system having an extended mobile base in accordance with an embodiment of the present invention;

FIG. 5 is a front elevation view of the elements of the collaborative robot welding system of FIG. 4;

FIG. 6 is a right side elevation view of the elements of the collaborative robot welding system of FIGS. 4 and 5;

FIG. 7 is a rear top perspective view of a collaborative robot welding system having a mobile base including a corner-mounted operator protection safety system in accordance with an embodiment;

FIG. 8 is a right rear elevation view of the collaborative robot welding system of FIG. 7;

FIG. 9 is an enlarged perspective view of an element of the corner-mounted operator protection safety system of the collaborative robot welding system of FIGS. 7 and 8;

FIG. 10 is a top plan view of the collaborative robot welding system of FIGS. 7-9;

FIG. 11 is a top plan view of the collaborative robot welding system of FIGS. 7-10 illustrating the safety sensing areas of the corner-mounted operator protection safety system;

FIG. 12 is a flow diagram of the operation of the safety sensing areas of the corner-mounted operator protection safety system of the collaborative robot welding system of FIGS. 7-11;

FIG. 13 is a front perspective view of the elements of a collaborative robot welding system having a stationary base or worktable adapted for use in the fabrication of large, welded assemblies;

FIG. 14 is a rear perspective view of the elements of the collaborative robot welding system shown in FIG. 13;

FIG. 15 is a side elevation view of the elements of the collaborative robot welding system shown in FIGS. 13 and 14;

FIG. 16 is a rear perspective view of the stationary worktable of the collaborative robot welding system shown in FIGS. 13-15 illustrating the selective positioning of multiple mechanical locking bases and robot arm mounted thereon in accordance with an embodiment;

FIG. 17 is a rear perspective view of the stationary worktable of the collaborative robot welding system shown in FIGS. 13-16 illustrating a robot arm releasably secured thereto by a magnetic mounting base in accordance with an embodiment;

FIG. 18 is a side elevation view of a collaborative robot arm positioned for attachment to a mechanical locking base of the types illustrated in FIGS. 13-16;

FIG. 19 is a side elevation view of the robot arm and mechanical locking base of FIG. 18 illustrating the robot arm mounted on the magnetic mounting base;

FIG. 20 is a perspective view of the robot arm and magnetic mounting base of the embodiment of FIG. 17 enlarged to more clearly illustrate the elements thereof;

FIG. 21 is a side elevation view of the robot arm and magnetic mounting base of the embodiment of FIG. 20;

FIG. 22 is a flow diagram depicting the process steps of an exemplary welding job cycle;

FIG. 23-A is a perspective view of a collaborative robot arm in accordance with an embodiment;

FIG. 23-B is a flow diagram illustrating the process workflow steps of the hang guided jogging movement of the robot arm;

FIG. 24 is a flow diagram of an AirMove workflow;

FIG. 25 is a pictorial representation or screen shot of an AirMove workflow defining a curved weld path as displayed on an input screen of a teach pendant;

FIG. 26 is a pictorial representation or screen shot of an AirMove workflow defining a linear weld path as displayed on an input screen of a teach pendant;

FIG. 27 is a flow diagram of a Pattern workflow;

FIG. 28 is a pictorial representation or screen shot of a Pattern Tool defining a non-linear weld path to be repeated as displayed on an input screen of a teach pendant;

FIG. 29 is a flow diagram of a SearchOffset workflow;

FIG. 30 is a pictorial representation or screen shot of a SearchOffset workflow defining offset values to turn on as displayed on an input screen of a teach pendant;

FIG. 31 is a pictorial representation or screen shot of a SearchOffset workflow defining offset values to turn off as displayed on an input screen of a teach pendant;

FIG. 32 is a pictorial representation or screen shot of a SearchOffset workflow defining specific offset values to turn on as displayed on an input screen of a teach pendant;

FIG. 33 is a flow diagram of a Search Part workflow;

FIG. 34 is a pictorial representation or screen shot of a Search Part workflow illustrating values identified during a search as displayed on an input screen of a teach pendant;

FIG. 35 is a flow diagram of a Tack Template workflow;

FIG. 36 is a pictorial representation or screen shot of a Tack Template workflow illustrating a tack approach point;

FIG. 37 is a pictorial representation or screen shot of a Tack Template workflow illustrating a tack weld point;

FIG. 38 is a pictorial representation or screen shot of a Tack Template workflow illustrating tack weld data;

FIG. 39 is a pictorial representation or screen shot of a Tack Template workflow illustrating a tack depart point;

FIG. 40 is a flow diagram of a Weld Template workflow;

FIG. 41 is a pictorial representation or screen shot of a Weld Template workflow illustrating a weld approach point and distance;

FIG. 42 is a pictorial representation or screen shot of a Weld Template workflow illustrating a weld start point;

FIG. 43 is a pictorial representation or screen shot of a Weld Template workflow illustrating weld data;

FIG. 44 is a pictorial representation or screen shot of a Weld Template workflow illustrating a weld end point;

FIG. 45 is a pictorial representation or screen shot of a Weld Template workflow illustrating a weld depart point and distance:

FIG. 46 is a flow diagram of a Stitch Template workflow;

FIG. 47 is a pictorial representation or screen shot of a Stitch Template workflow illustrating a stitch approach point and distance;

FIG. 48 is a pictorial representation or screen shot of a Stitch Template workflow illustrating a stitch start point;

FIG. 49 is a pictorial representation or screen shot of a Stitch Template workflow illustrating stitch weld data;

FIG. 50 is a pictorial representation or screen shot of a Stitch Template workflow illustrating stitch weld length and spacing data;

FIG. 51 is a pictorial representation or screen shot of a Stitch Template workflow illustrating a stitch end point;

FIG. 52 is a pictorial representation or screen shot of a Stitch Template workflow illustrating a stitch depart point and distance;

FIG. 53 is a flow diagram of a Root Template workflow that will subsequently be used with a Replay Template in a Multi-Pass Fashion;

FIG. 54 is a pictorial representation or screen shot of a Root Template workflow illustrating a root approach point and distance;

FIG. 55 is a pictorial representation or screen shot of a Root Template workflow illustrating a root start point;

FIG. 56 is a pictorial representation or screen shot of a Root Template workflow illustrating root weld data;

FIG. 57 is a pictorial representation or screen shot of a Root Template workflow illustrating a root end point;

FIG. 58 is a pictorial representation or screen shot of a Root Template workflow illustrating a root depart point and distance;

FIG. 59 is a flow diagram of a Replay Template workflow;

FIG. 60 is a pictorial representation or screen shot of a Replay Template workflow illustrating a replay approach point and distance;

FIG. 61 is a pictorial representation or screen shot of a Replay Template workflow illustrating a replay pass path data;

FIG. 62 is a pictorial representation or screen shot of a Replay Template workflow illustrating a replay pass offset data;

FIG. 63 is a pictorial representation or screen shot of a Replay Template workflow illustrating a replay pass weld data;

FIG. 64 is a pictorial representation or screen shot of a Replay Template workflow illustrating a replay pass depart point and distance;

FIG. 65 is a pictorial representation or screen shot of a WeldThru/WeldEnd Template illustrating a linear weld thru move;

FIG. 66 is a pictorial representation or screen shot of a WeldThru/WeldEnd Template illustrating a circular weld thru move; and

FIG. 67 is a pictorial representation or screen shot of a WeldThru/WeldEnd Template illustrating a circular weld end move.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claim and its equivalents.

### Overview of Welding System

The collaborative robot welding system of the present invention addresses the afore-mentioned needs of the industry by providing a welding system that may be taken to the work material, set up, and placed in production in less than a few hours. The collaborative robot welding system includes a user interface or a teach pendant adapted to allow control system programming to be completed for any given job in an intuitive and graphical manner without requiring significant and specific education, training or computer programming/coding experience or skills. Accordingly, in a scarce labor market, where an extreme shortage of skilled welders exists, the collaborative robot welding system of the present invention permits manufacturers of welded products to meet the high demand for those products economically.

In operation, the operator/programmer either brings the work materials to be welded to the collaborative robot or, alternatively, brings the robot to the work material. If the collaborative robot is taken to the work material, the welder is plugged into available single phase or three phase wall power and the collaborative robot is plugged into an available 120V outlet. Once both devices are powered on, the operator/programmer starts positioning the collaborative robot for the work material to be welded. The first positions that the operator/programmer will teach are clearance moves of the welding arm, designated as “AirMove's” to position the robot in preparation for the welding the task at hand. The primary means of moving the collaborative robot and the welding gun to the work material is via a programming button that releases the robot into a hand-guided jogging mode where the operator/programming can push/pull the robot into the appropriate position. When the operator/programmer starts positioning the collaborative robot, he/she ensures they have a welding print or a welding procedure that will be used to identify the size and type of welding to be applied to the work material. If the desired work material will vary in positional location or the collaborative robot is moved to the work material, tactile searching/sensing is needed to ensure the trajectory of the robot is properly placed in the joint considering this variation. If one of these conditions exists, the operator/programmer plans out the searching scheme and weld path offsets if needed.

If searches are required to gather more data, the operator/programmer zeros out these searches treating the part to be welded as the baseline part for correlation of searches to all subsequent weld templates. Once the operator/programmer has added searches and appropriate offset activation, the appropriate weld templates can be added. Each of these welds may be a single segment linear weld, a single segment circular weld, or any additional segment combination to trace the shape of the welded component. The required welds might also be continuous welds, intermittent stitch welds, or multipass welds that take advantage of the programming technique referred to as storage and replay where the collaborative robot records the root pass and replays this on subsequent passes positionally offsetting to achieve the desired weld size and shape. These various types of welds will be added using the built in programming tools for each particular type of weld that is added. Once the welds have been added to the program, the operator/programmer selects the welding process that is needed and if the appropriate weld process is not in the system, the process will be developed using an existing set of data that is adjusted for a larger or smaller weld. The process of adding searches, if needed, and weld templates is repeated for all necessary welds across the work material to be welded. Between each of these sets of searches and weld templates any necessary AirMove's will be added for clearance or conduit bundle cable management. Once all necessary moves have been added to the collaborative robot, the operator/programmer saves the program in the robot for future repetitive use. In either case where the work material was brought to the collaborative robot or the collaborative robot was taken to the work material, the position of the robot relative to the work material must be recorded or outlined on the floor of the production facility.

### Overview of System for Cutting

First, the operator/programmer either brings the work materials to be plasma cut to the collaborative robot or, alternatively, brings the robot to the work material. If the collaborative robot is taken to the work material, the plasma cutting machine is plugged into available three phase wall power and the collaborative robot is plugged into an available 120V outlet. Once both devices are powered on, the operator/programmer starts positioning the collaborative robot for the work material to be plasma cut. The first positions that the operator/programmer will teach are clearance AirMove's to position the robot in preparation for the cutting. The primary means of moving the collaborative robot and the plasma cutting head to the work material is via the programming button that releases the robot into a hand-guided jogging mode where the operator/programming can push/pull the robot into the appropriate position. When the operator/programmer starts positioning the collaborative robot, he/she ensures they have a cutting or assembly print that will be used to identify shape and location of the cutting to be performed on the work material. If the desired work material will vary in positional location or the collaborative robot is moved to the work material, tactile searching/sensing is needed to ensure the trajectory of the collaborative robot is properly placed in the joint considering this variation. If one of these conditions exists, the operator/programmer plans out the searching scheme and where the offsets will be needed for the cutting process that will be performed on the work material.

If searches are needed, the operator/programmer zeros out stored searches treating this part as the baseline part for correlation of searches to all subsequent cut templates. Once the operator/programmer has added in searches and appropriate offset activation, the appropriate cut templates can be added. Each of the cuts may be a shape cut such as a slot, square, rectangle, circle, etc. or a free multisegmented path cut based on the cutting or assembly print. The various types of cuts will be added using the built in programming tools for each particular type of cut that is added. Once the cuts have been added to the program, the operator/programmer selects the appropriate cutting process, and if the appropriate cutting process is not already saved in the system, it will be developed using an existing set of data that is adjusted by increasing or decreasing the travel speed while adjusting amperage based on the thickness. This process of adding searches, if needed, and cut templates is repeated for all necessary cuts across the work material. Between each of these sets of searches and cut templates, any necessary AirMove's will be added for clearance or conduit bundle cable management. Once all necessary moves have been added to the collaborative robot, the operator/programmer saves the program in the robot for future repetitive use. In either case, where the work material was brought to the collaborative robot or the robot was taken to the work material, the position of the collaborative robot relative to the work material must be recorded or outlined on the floor.

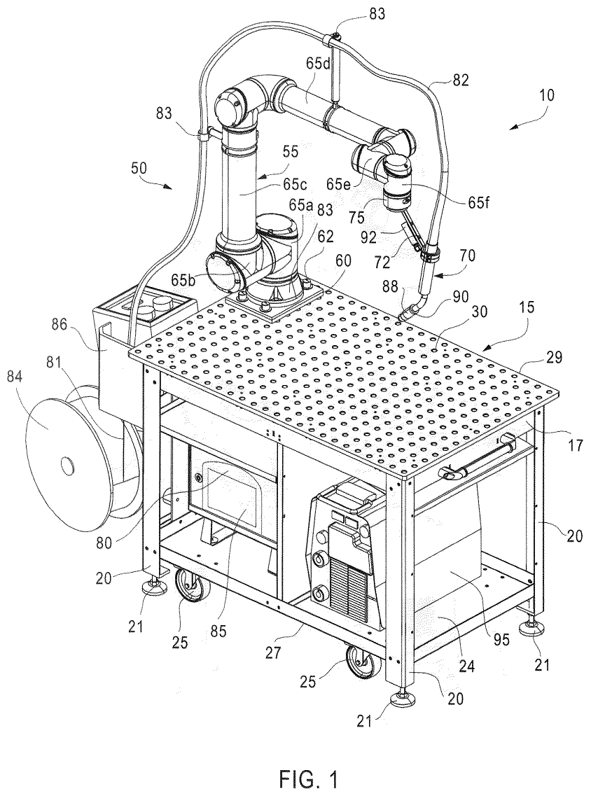

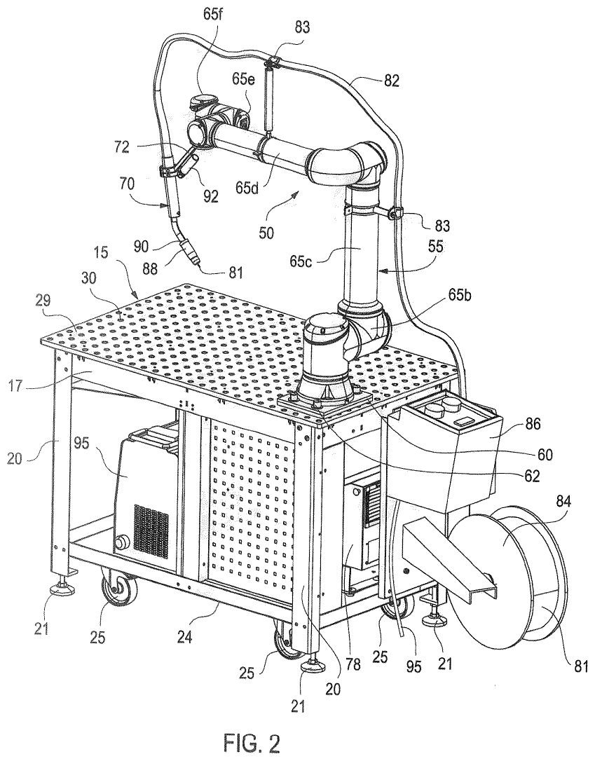

Referring initially to FIGS. 1 and 2, an exemplary collaborative robot welding system, referred to hereinafter as the welding system for purposes of brevity, is shown generally at the numeral 10. The welding system includes a mobile worktable, base or cart 15, as the terms may be used interchangeably herein, having a frame 17, a plurality of supporting legs 20, each including a levelling device or foot 21 attached thereto, a storage area or platform 24 having wheels or casters 25 mounted to a bottom surface 27 thereof, and a gridded upper work surface or table 29. The upper work surface includes a plurality of apertures 30 formed therein, each of the apertures being adapted to releasably receive a clamp or other securement device for holding a workpiece, fixture or weld assembly in a fixed position during the performance of a welding sequence using the welding system.

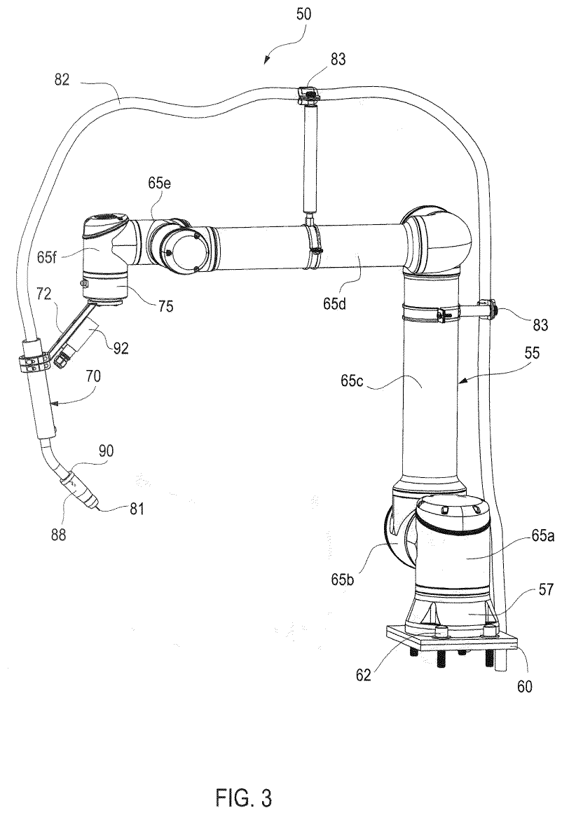

The welding system 10 further includes a collaborative robot system 50 (known in the art as a cobot), such as a Universal Robots™ UR10e collaborative industrial robot, which is shown in greater detail in FIG. 3. However, it is to be understood that collaborative robot systems either specifically designed and built for individual applications or other generally commercially available collaborative robot systems may also be used without departing from the scope of the present invention. The collaborative robot system comprises a robot arm 55 operatively connected to a base 57, which, in turn, is mounted on an electrically isolating pad 60 secured by suitable fasteners 62 to the upper work surface 29. The robot arm includes a plurality of arm segments 65a-65f sequentially pivotally and/or rotatably interconnected to one another and structured and arranged to have a reach length or distance which depends upon the size of the robot arm selected for use in the system 50 and the lengths of its individual segments. A built-in safety feature (not shown) in the robot arm is structured and arranged to interrupt movement of the arm, should it come in contact with the operator or another object. A welding or cutting implement or torch 70 is secured via an attachment 72 to a distal end 75 of the robot arm, the implement being universally positionable and translatable along a preselected weld path in response to instructions from a robot controller 78, teach pendant 80 and application programming interface (API) display 85. In the embodiment of FIGS. 1-3, by way of example and not of limitation, the implement 70 is depicted in the form of a welding torch representative of the type used in Gas Metal Arc Welding (GMAW) processes; however, it is to be understood that the system of the present invention may be used with any materials joining or cutting process without departing from the scope of the present invention. It is to be understood that the system 10 may be used for cutting applications by replacing the welding implement 70 with a plasma cutting torch or other cutting implements needed for a particular cutting application.

Welding consumables such as protective shielding gas, cutting gas, granular flux material and welding wire 81 are delivered to the welding implement via conduit or welding torch bundle 82 secured to the robot arm segments 65c and 65d by conduit or bundle management brackets 83. The wire is stored in a suitable wire storage apparatus such as a drum or, by way of example and not of limitation, on a wire spool 84 and fed by a wire feed mechanism 86 from the spool through the conduit or bundle and to a weld joint assembly via a weld nozzle 88 operatively connected to a distal end 90 of the torch. A programming or hand-guided jog button 92 is secured to the attachment 72 and is operatively connected to the robot controller 78 and teach pendant 80 and, as will be described in greater detail below, is adapted to allow an operator to set up and program the welding system in an intuitive and graphical manner. Shielding gas is delivered from a central gas supply system or from individual gas cylinders via the torch bundle to the weld nozzle, as is known in the art. Power is provided to the welding or cutting implement via power supply 95, and the power supply, robot controller, teach pendant, wire feed mechanism, and any ancillary power tools an operator may need all may be operatively connected to single phase power, for example, 120V power for the collaborative robot system and 240V power for the power supply. Optionally, the power supply may be connected to 208V, 480V or 575V three phase power.

The availability of conventional shop power combined with the portability of the worktable contribute to the overall flexibility and adaptability of the welding system. It can be brought to the location of the work material and set up anywhere in a shop or in the field quickly with little lead time. The welding system in the embodiment of FIGS. 1 and 2 mounted on the worktable occupies a small area having a full system footprint of approximately three (3) feet wide and six (6) feet deep, and does not require a large investment in utilities, dedicated factory space, safety guards and materials handling equipment. The welding system of the present invention is particularly adaptable for high mix, low production small or medium-sized piece parts such as brackets, angles, handles, and the like.

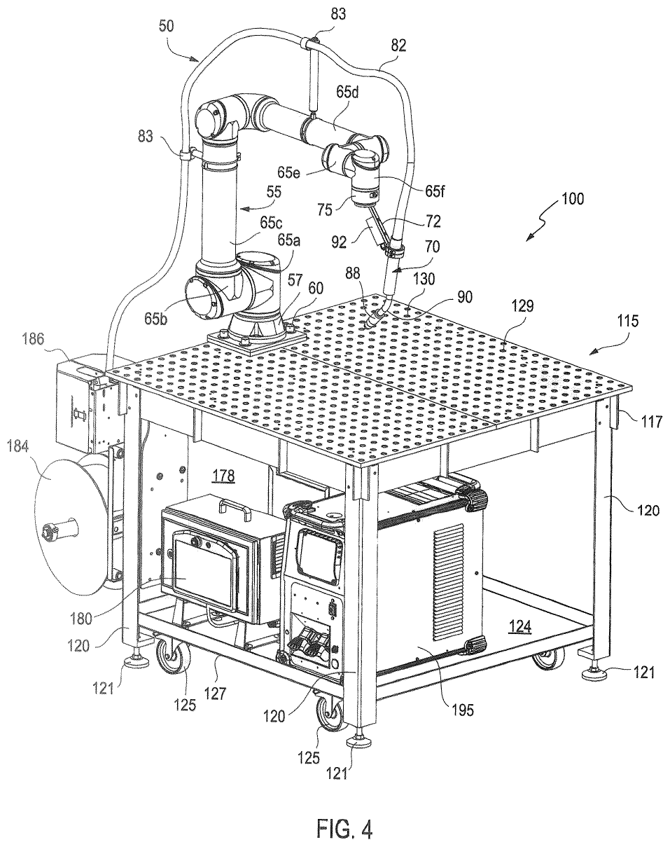

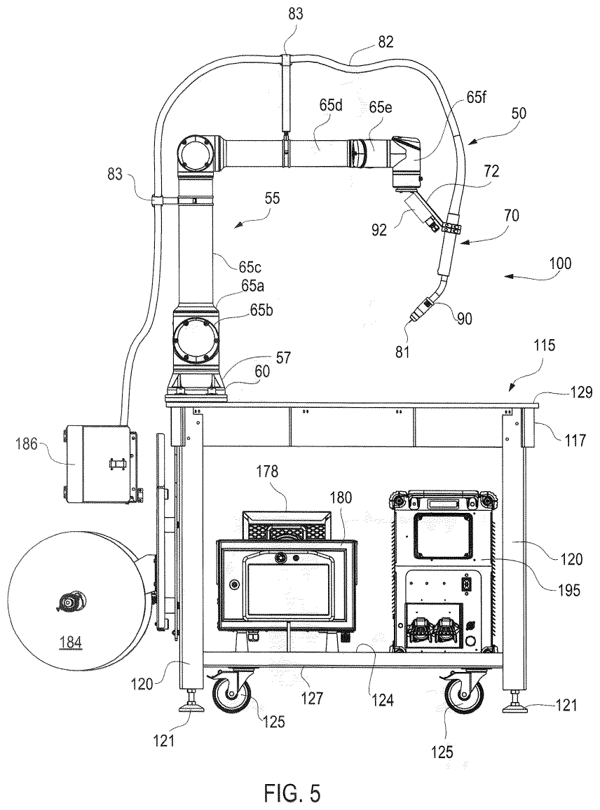

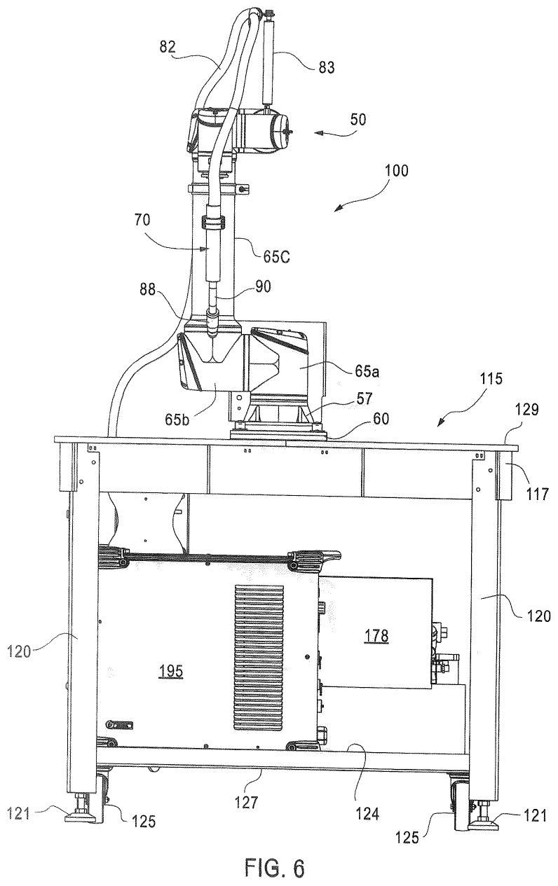

Referring now to FIGS. 4-6, a collaborative robot welding system 100 having an extended worktable or mobile cart 115 is illustrated in accordance with an embodiment. Similar in construction and operation to the embodiment of FIGS. 1 and 2, welding system 100 includes a worktable or mobile cart 115 having a full system footprint of approximately six (6) feet wide and six (6) feet deep. The extended worktable or mobile cart includes a frame 117, a plurality of supporting legs 120, each including a levelling device or foot 121 attached thereto, a storage area or platform 124 having wheels or casters 125 mounted to a bottom surface 127 thereof, and a gridded upper work surface or table 129. The upper work surface includes a plurality of apertures 130 formed therein, each of the apertures being adapted to releasably receive a clamp or other securement device for holding a workpiece, fixture or weld assembly in a fixed position during the performance of a welding sequence using the welding system.

The welding system 100 further includes a collaborative robot system or cobot 50 as shown in FIG. 3 and described in detail above with respect to the embodiment of FIGS. 1 and 2. For purposes of clarity and simplicity, the same robot system component numeric identifiers are also used in the embodiment of FIGS. 4-6 that are shown in FIG. 3. Collaborative robot systems either specifically designed and built for individual applications or other generally commercially available collaborative robot systems may also be used in the embodiment of FIGS. 4-6 without departing from the scope of the present invention.

Welding consumables such as protective shielding gas, granular flux material and welding wire 81 are delivered to the welding implement via conduit or welding torch bundle 82 secured to the robot arm segments 65c and 65d by conduit or bundle management brackets 83. The wire is stored in a suitable wire storage apparatus such as a drum or, by way of example and not of limitation, on a wire spool 184 and fed by a wire feed mechanism 186 from the spool through the conduit or bundle and to a weld joint assembly via a weld nozzle 88 operatively connected to a distal end 90 of the torch. A programming or hand-guided jog button 92 is secured to the attachment 72 and is operatively connected to the robot controller 178 and teach pendant 180 and is adapted to allow an operator to set up and program the welding system in an intuitive and graphical manner. Shielding gas is delivered from a central gas supply system or from individual gas cylinders via the torch bundle to the weld nozzle, as is known in the art. As applicable to all of the embodiments of the collaborative welding system herein described, power is provided to the welding implement via welding power supply 195, and the welding power supply, robot controller, teach pendant, wire feed mechanism, and any ancillary power tools an operator may need all may be operatively connected to single phase power, for example, 120V power for the collaborative robot system and 240V power for the welding power supply. Optionally, the welding power supply may be connected to 208V, 480V or 575V three phase power.

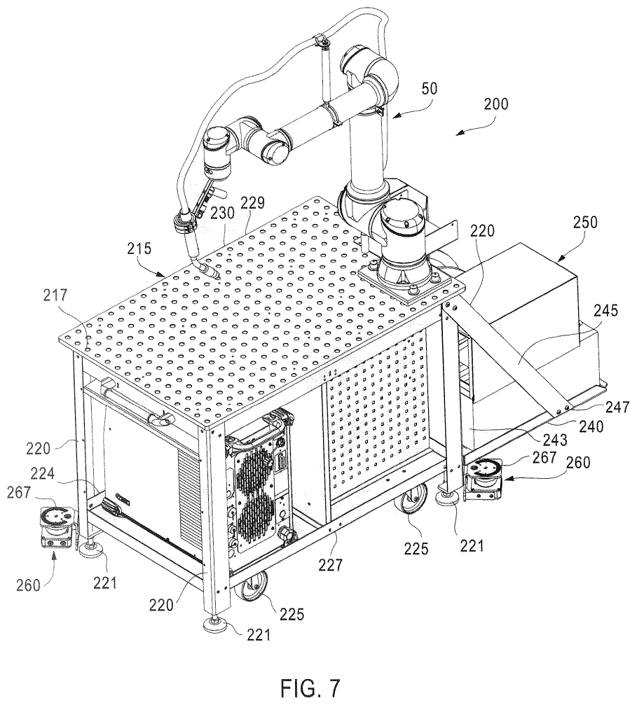

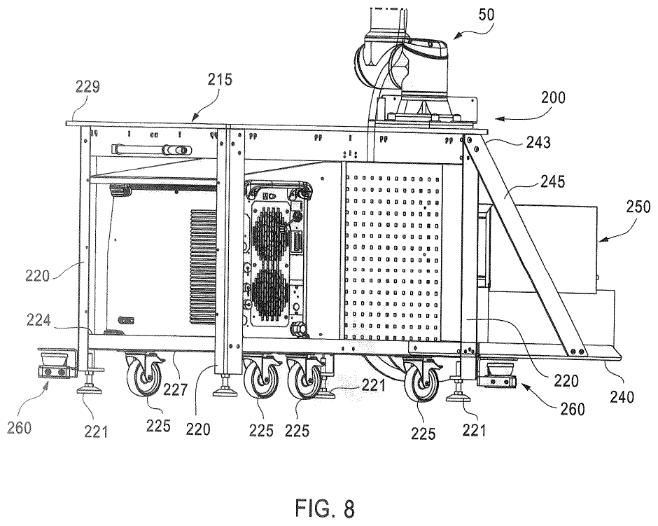

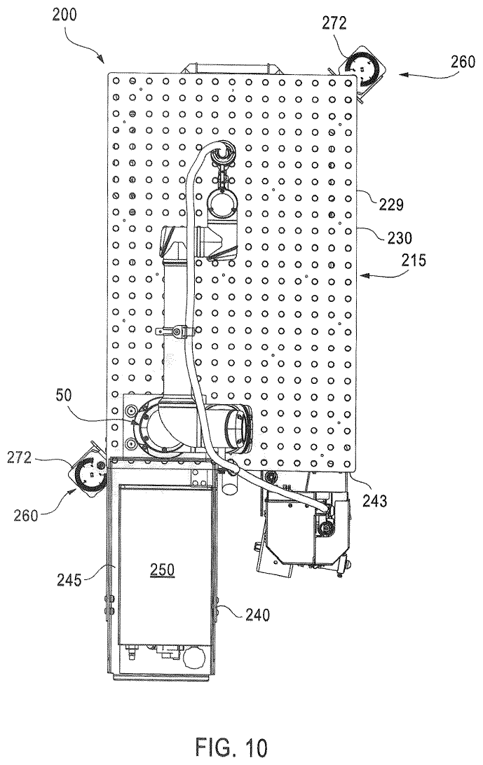

FIGS. 7-11 illustrate the elements and features of a collaborative robot welding system 200 which includes a mobile worktable, base or cart 215 having a corner-mounted operator protection safety system 260 secured thereto in accordance with an embodiment of the present invention. Similar in construction and operation to the embodiments of FIGS. 1 and 4, the worktable or mobile cart 215 of welding system 200 may have a full system footprint of approximately three (3) feet wide and six (6) feet deep as shown in FIG. 1 or, alternatively the extended size of approximately six (6) feet wide and six (6) feet deep as shown in the embodiment of FIG. 4. The worktable or mobile cart includes a frame 217, a plurality of supporting legs 220, each including a levelling device or foot 221 attached thereto, a storage area or platform 224 having wheels or casters 225 mounted to a bottom surface 227 thereof, and a gridded upper work surface or table 229. The upper work surface includes a plurality of apertures 230 formed therein, each of the apertures being adapted to releasably receive a clamp or other securement device for holding a workpiece, fixture or weld assembly in a fixed position during the performance of a welding sequence using the welding system. The collaborative robot welding system 200 further includes a platform or storage shelf 240 operatively connected to an end 243 of the cart 215 and supported by a pair of diagonally extending braces 245 secured at a first end 247 to the platform and at a second end 249 to the end 243 of the cart. In this embodiment 200, the collaborative robot welding system 200 includes a water cooling system 250 for a welding torch 70 as may be needed for larger welding applications where generated heat may require faster dissipation than is available via air cooling.

The welding system 200 further includes a collaborative robot welding system or cobot 50 as shown in FIG. 3, the individual elements of which are described in detail above with respect to the embodiments of FIGS. 1 and 4. As noted earlier, collaborative robot systems either specifically designed and built for individual applications or other generally commercially available collaborative robot systems may also be used in the embodiment of FIGS. 7-11 without departing from the scope of the present invention.

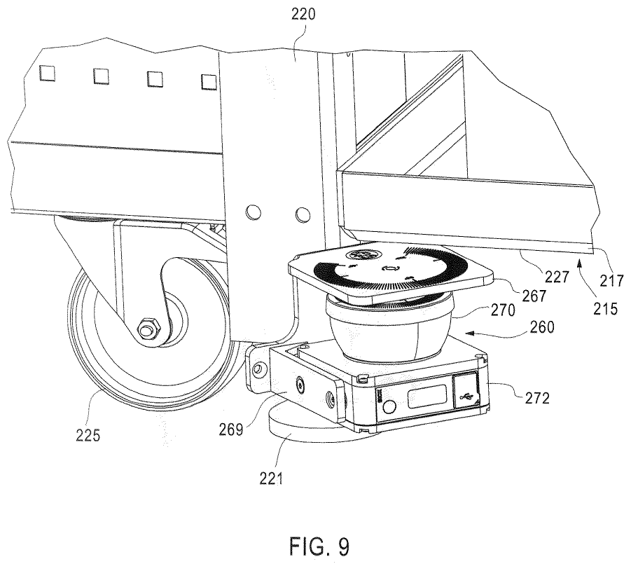

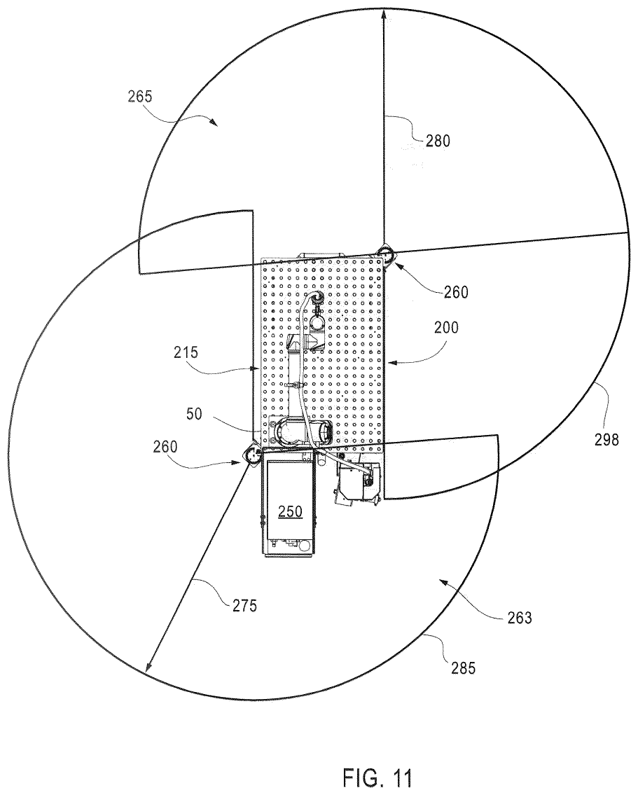

Referring now to FIG. 9, the elements of the corner-mounted operator protection safety system 260, referred to hereinafter as “the LIDAR safety system or alternatively, the safety system”, as appropriate in the context is shown in greater detail. LIDAR is an acronym for light detection and ranging or, alternatively, laser imaging, detection, and ranging, a system which uses ultraviolet (UV), visible or near infrared (NIR) light to detect objects and to determine ranges or distances from the emitter/detector to the object. The LIDAR system of the corner-mounted operator protection safety system 260 of the instant invention is used to detect the presence of an operator, other personnel or a vehicle such as a forklift in preselected safety zones or non-visible safety barriers 263, 265 surrounding the collaborative robot welding system 200. These safety zones or barriers are shown in FIG. 11 and are generated by the LIDAR scan projected out by the system. When an object is detected in one of the zones, the operating speed of the robot system is reduced for safety purposes. Coupled with the built-in safety system of the robot arm, which stops its movement when the arm contacts an object, the system possesses dual chain safety feature redundancy. This feature also enhances production rates, inasmuch as the system may be operated confidently at higher speeds under normal conditions knowing that if an unsafe condition is detected, the system will respond proactively to protect the operator and other personnel in the area.

As illustrated in FIG. 9, the LIDAR safety system is adjustably and rotatably secured to the bottom surface 227 of the mobile cart 215 by brackets 267 and 269. The operating and control components of the system are contained within cylindrical housing 270 and in projector housing 272 which are adjustably positionable to control the radii 275, 280 and the corresponding circumference ranges 285, 290 of the safety zones 263, 265 generated by the LIDAR safety system scan, respectively.

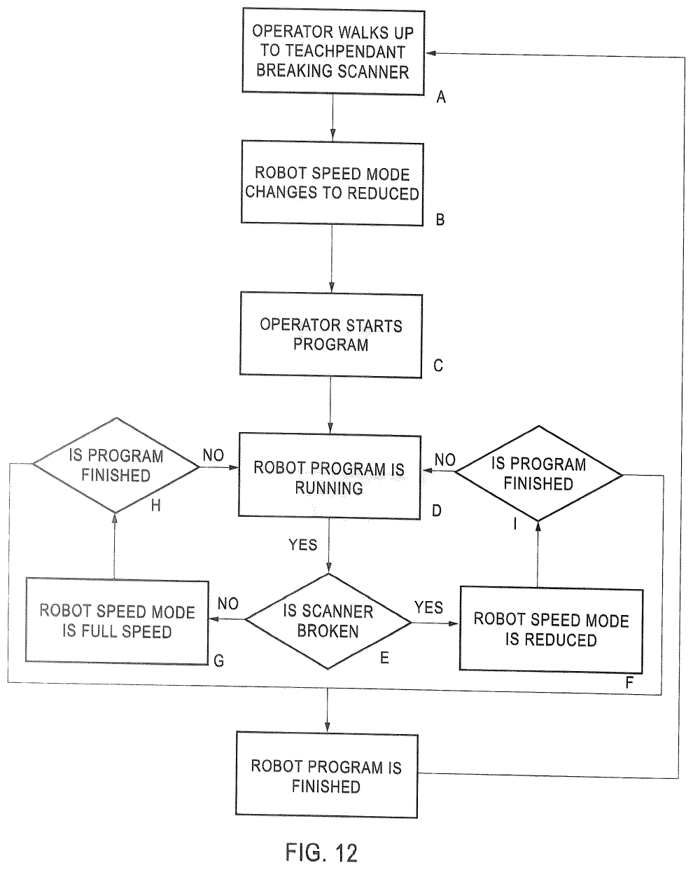

The operational flow chart of the LIDAR safety system is presented in FIG. 12. When the collaborative robot welding system has been programmed and set up for a particular job and has completed the programmed welding tasks or if the system is sitting idle, if an operator walks up to the system, he or she will enter one or both of the safety zones 263, 265 thereby breaking the non-visible safety barrier. In response, the robot speed mode is adjusted downward at step B, and the operating speed is reduced to a preselected safe level but is not shut down. At step C, the operator, who is now within the safety zones, may safely and confidently perform programming operations, unload work materials already welded, load and adjust new work materials for the next welding cycle, and perform other tasks associated with operating the cobot 50. The operator then selects the program to execute with the new work materials and presses the start button on the robot either via the pendant or operator panel. The program starts and the operator walks out of the non-visible safety barrier. The robot then speeds up to the allowable maximum speed while continuing the current program it is executing. At step D, the LIDAR safety system continually checks to determine if the robot program is running and if the scan is interrupted at step E, which would indicate that the operator has reentered the safety zones. If the scanner indicates that the operator is still in the safety zones, the robot operating speed is maintained at a reduced speed level, step F. If the scanner is uninterrupted, which indicates that the operator has completed his or her tasks within the safety zone and moved out of them, the system returns the robot operating speed to the preselected full operating speed for the task being performed at step G. The system continuously checks for any breakage of the non-visible safety barrier or obstacle that would slow the robot operating speed down, step E, or completion of the program at steps H and I, thereby providing closed loop feedback to the control system of the status of the robot program. If the system detects that the program is finished at step J, the operation is complete and the operator may approach the mobile cart 215 to perform a new setup, reprogram the robot or to execute other required tasks. The main usefulness for the safety system is speeding up all the “non-process” moves to reduce the cycle time of the system to the most efficient cycle time possible with any given job.

The embodiments depicted in FIGS. 1-11 further illustrate the flexibility and adaptability of the welding system 10 of the present invention, inasmuch as the portability of the system coupled with the reach distance or length of the robot arm allows the system to be used to fabricate weldments on assemblies or structures that may be difficult or uneconomical to move or, alternatively which may be permanently fixed to larger structures. For example, storage vessels, petrochemical processing equipment, or large open pit mining shovels may experience structural failures, weld cracking or other problems which may require field repair by welding. The entire welding system including all of the individual components, namely, the worktable, the welding power supply, robot controller, teach pendant, and wire feed mechanism may be positioned as a unit on an elevated platform, scaffolding, a cherry picker (boom lift) or a scissor lift for performing welding operations in relatively inaccessible locations. Alternatively, the individual components may be positioned separately independently of the worktable, and the mechanically secured base 57 may be replaced by a magnetic base such as will be described below in greater detail affixed to a sidewall, roof or ceiling portion of a steel structure to perform out of position welding operations, i.e., fabricating vertical or overhead weldments and weldments on large stationary structures in both indoor manufacturing and field service maintenance applications

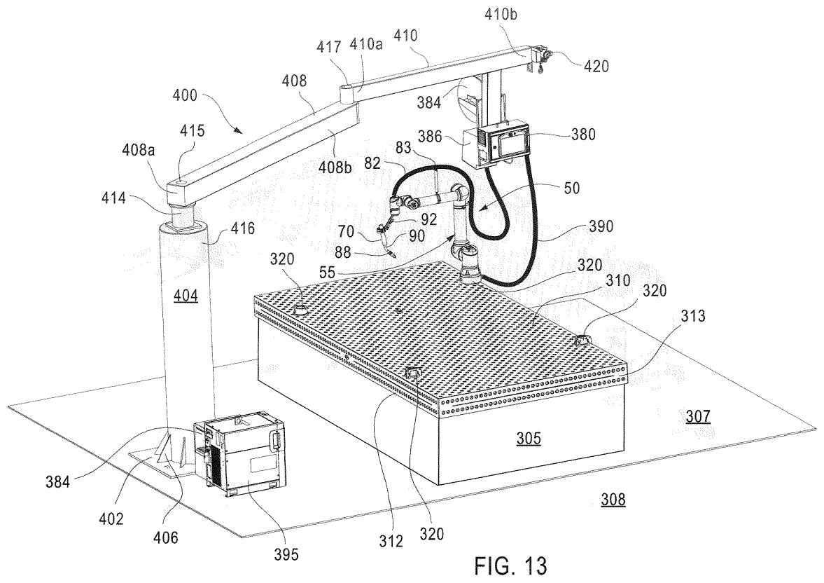

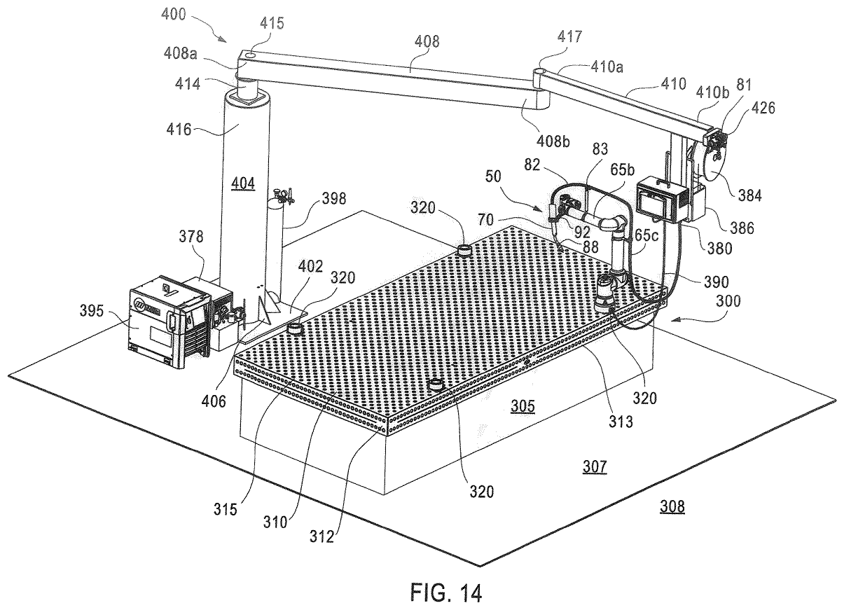

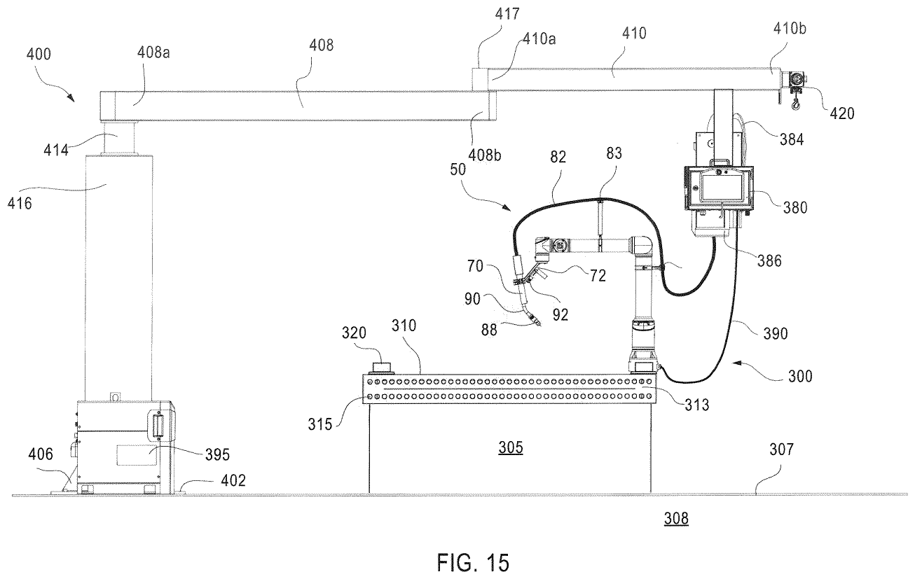

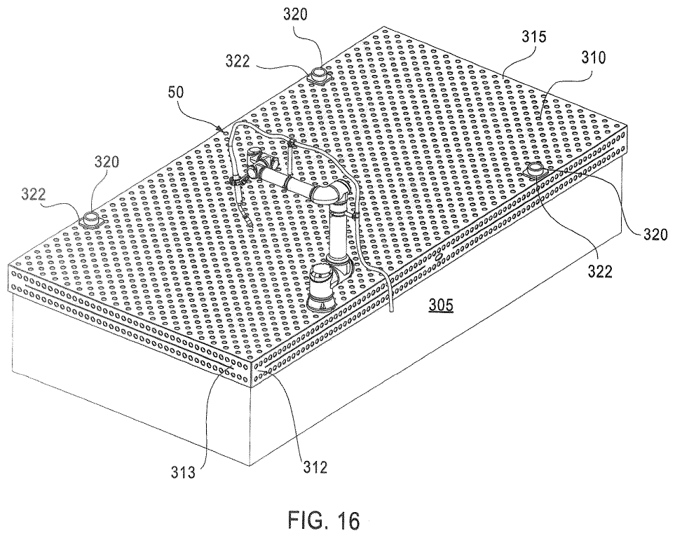

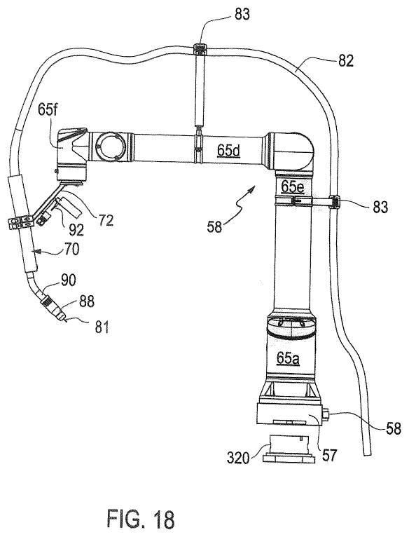

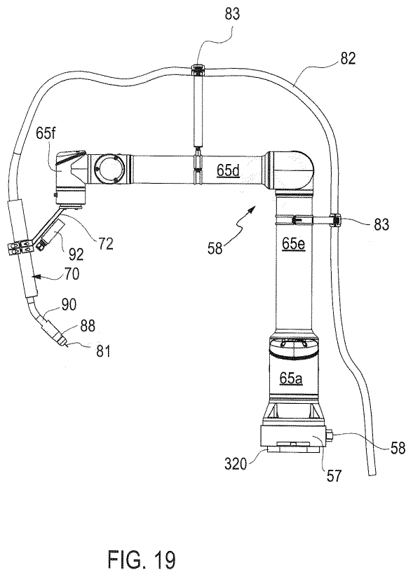

A collaborative robot welding system having a stationary base or worktable adapted for use in the fabrication of large, welded assemblies is shown at 300 in FIGS. 13-15. The system 300 includes a stationary base 305 positioned within a designated work area on a prepared floor surface pad 307 to isolate the system 300 electrically from the surrounding environment and the floor 308 of the fabricating facility. The station base includes a gridded upper work surface or table 310 having longitudinal and transverse edges or side portions 312 and 313 respectively, the table and each of the edges including a plurality of apertures 315 formed therein, each of the apertures being adapted to releasably receive one or more clamps or other securement devices for holding work materials, fixtures or weld assemblies in a fixed position during the performance of a welding sequence using the welding system. In the embodiment shown, the stationary base includes a plurality of bases 320 operatively secured thereto via suitable fasters such as bolts 322, which are shown in FIG. 16. By way of example and not of limitation, each of the bases may be a GRIP connector such as an MGW Connector or a SWS Connector manufactured by GRIP GmbH, Dortmund, Germany; however, it is to be understood that other robot system mounting devices may be used without departing from the scope of the present invention. Depending upon the task, any number of mounting devices may be used and secured to the gridded upper work surface or table 310 or along each edge 312, 313 thereof, thus permitting welding or cutting operations to be performed on work material of unusual configurations and/or upon multiple individual assemblies at the same time, the number being limited solely by the relative geometric sizes thereof and the space available on the work surface or table 310. Referring to FIG. 18, a collaborative robot welding system 50 as described below in greater detail is depicted in position above one of the plurality of bases 320 prior to securing it thereto. FIG. 19 shows the collaborative robot welding system operatively and releasably connected via base member 57 and lock mechanism 58 to one of the plurality of bases 320 after it is positioned thereon using the hoist 420.

As described above with respect to the embodiments of FIGS. 1, 4 and 7, the collaborative robot welding system 300 further includes a collaborative robot system or cobot 50 as shown in FIG. 3 and described in detail above. For purposes of clarity and simplicity, the same robot system component numeric identifiers are also used in the embodiment of FIGS. 13-19 that are shown in FIG. 3. Collaborative robot systems either specifically designed and built for individual applications or other generally commercially available collaborative robot systems may also be used in the embodiment of FIGS. 13-19 without departing from the scope of the present invention.

Welding consumables such as protective shielding gas, granular flux material and welding wire 81 are delivered to the welding implement via conduit or welding torch bundle 82 secured to the robot arm segments 65c and 65d by conduit or bundle management brackets 83. The wire is stored in a suitable wire storage apparatus such as a drum or, by way of example and not of limitation, on a wire spool 384 and fed by a wire feed mechanism 386 from the spool through the conduit or bundle and to a weld joint assembly via a weld nozzle 88 operatively connected to a distal end 90 of the torch. A programming or hand-guided jog button 92 is secured to the attachment 72 and is operatively connected to a robot controller 378 and teach pendant 80 via cable 390 and, as will be described in greater detail below, is adapted to allow an operator to set up and program the welding system in an intuitive and graphical manner. Shielding gas is delivered from a central gas supply system or from individual gas cylinders 398 via the torch bundle to the weld nozzle, as is known in the art. Power is provided to the welding implement via welding power supply 395, and the welding power supply, robot controller, teach pendant, wire feed mechanism, and any ancillary power tools an operator may need all may be operatively connected to single phase power, for example, 120V power for the collaborative robot system and 240V power for the welding power supply. Optionally, the welding power supply may be connected to 208V, 480V or 575V three phase power, as noted with respect to embodiments of the instant invention described above.

Work material, fixtures and assemblies to be welded are moved from shop transportation vehicles such as forklifts, pallets and the like to the worktable 310 by a boom assembly 400. secured to the surface pad 307 and underlying floor 308 by a base plate 402 The boom assembly includes a main vertically extending column 404 attached to the base plate and supported by a plurality of gusset plates 406. A pair of horizontally extending pivotally interconnected boom segments 408, 410, each having first and second ends 408a, 410a and 408b, 410b respectively are pivotally secured at a first end 408a of boom segment 408 via connector 414 and pin 415 to a top end portion 416 of the column 404. The boom segments are pivotally interconnected at ends 408b and 410a by pin 417 extending therethrough. A winch or hoist 410 is mounted on end 410a and adapted to move work material, fixtures and assemblies to and from the worktable 310 and to selectively move and position one or more collaborative robot welding systems 300 thereon.

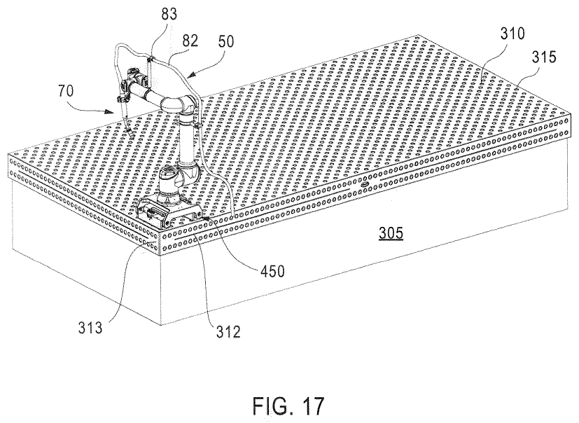

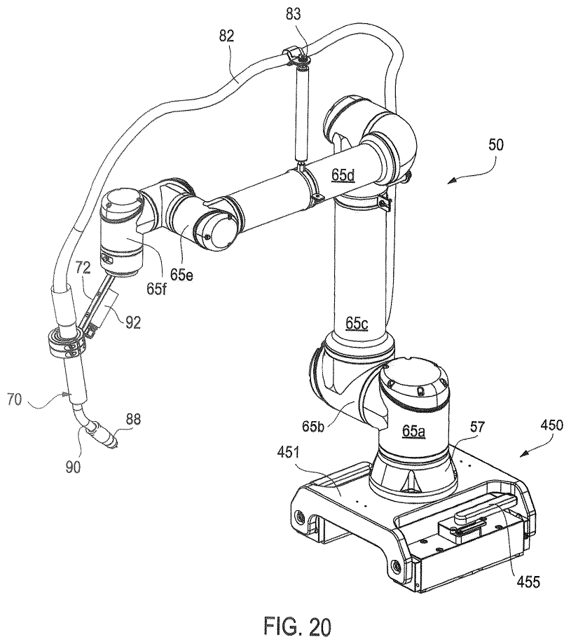

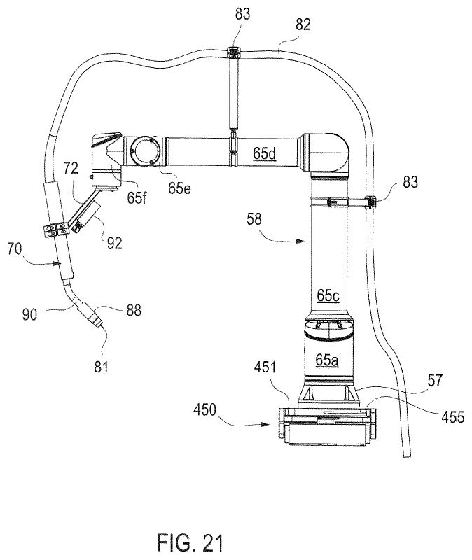

Referring now to FIGS. 17, 20 and 21 a collaborative robot welding system 50 is shown operatively connected to the worktable 310 by a magnetic base 450 such a Magswitch UR 10 isolated cobot magnetic base manufactured by Magswitch Technology, Lafayette, Colorado. The magnetic base is releasably positioned at any location suitable for the assembly to be welded and the collaborative robot welding system 50 is positioned thereon via the hoist 420. The base 57 of the collaborative robot welding system 50 is adapted to fit over a cylindrical magnetic attachment member located on a top surface 451 of the magnetic base, and the collaborative robot welding system 50 is releasably secured thereto via activation lever 455 which moves magnets positioned in the base closer together, thereby creating sufficient securing forces to maintain the collaborative robot welding system in position. After welding operations have been completed, the collaborative robot welding system 50 may be released by moving the activation lever in the opposite direction, and the hoist 420 is used to reposition the collaborative robot welding system at another selected location on the worktable.

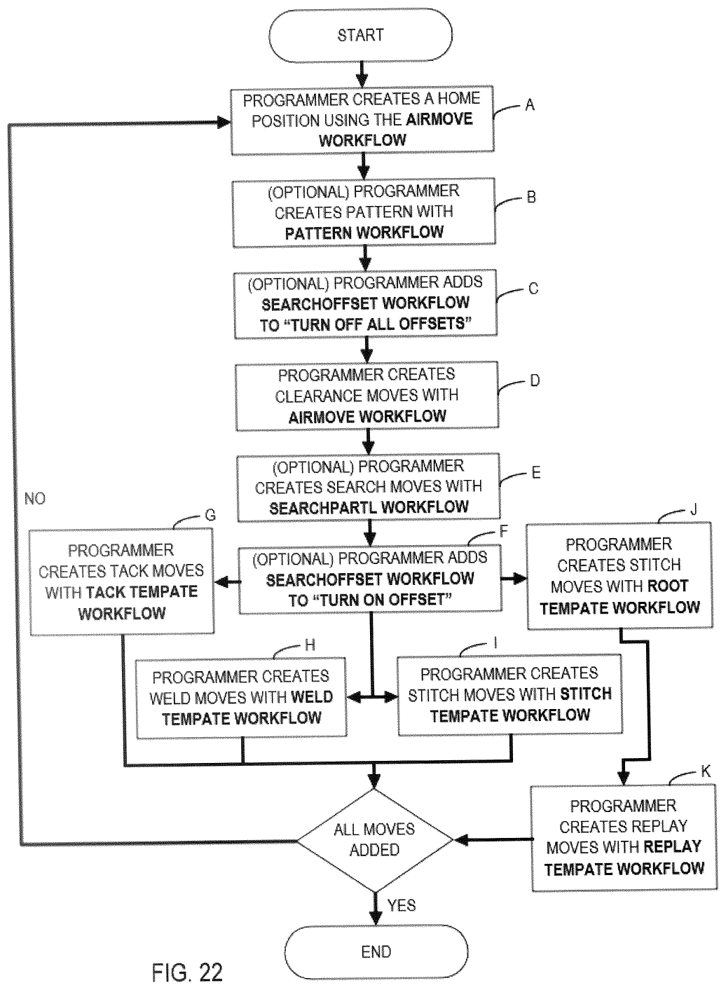

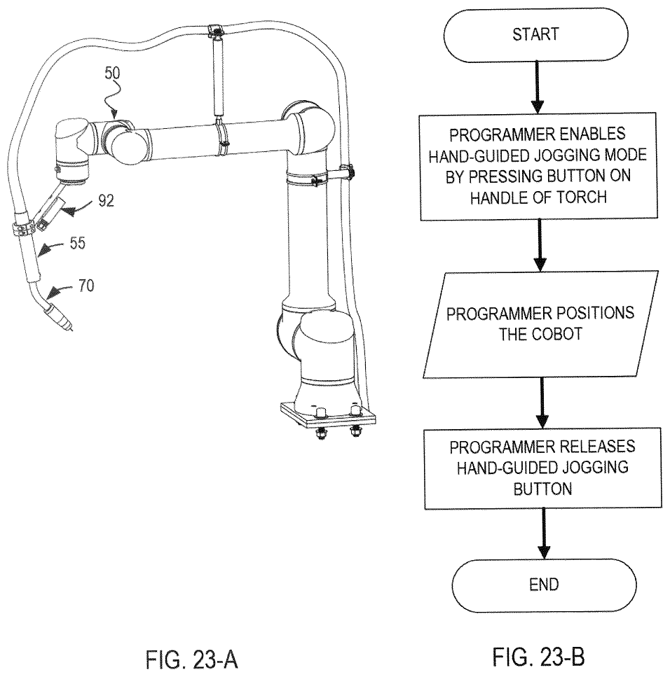

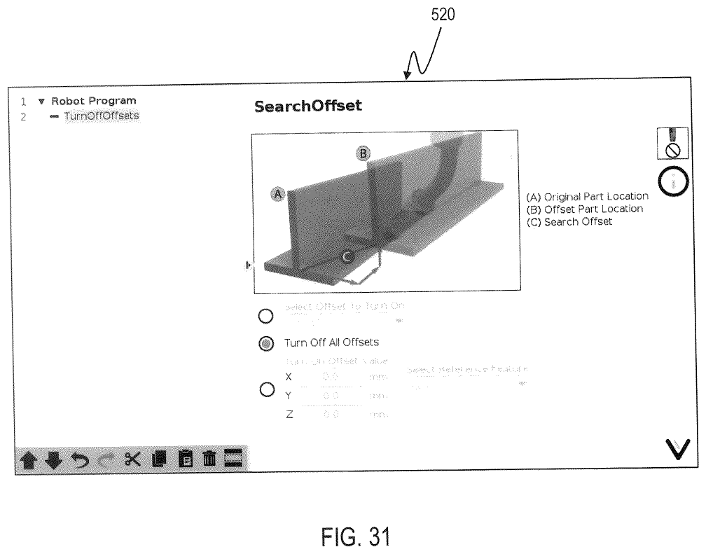

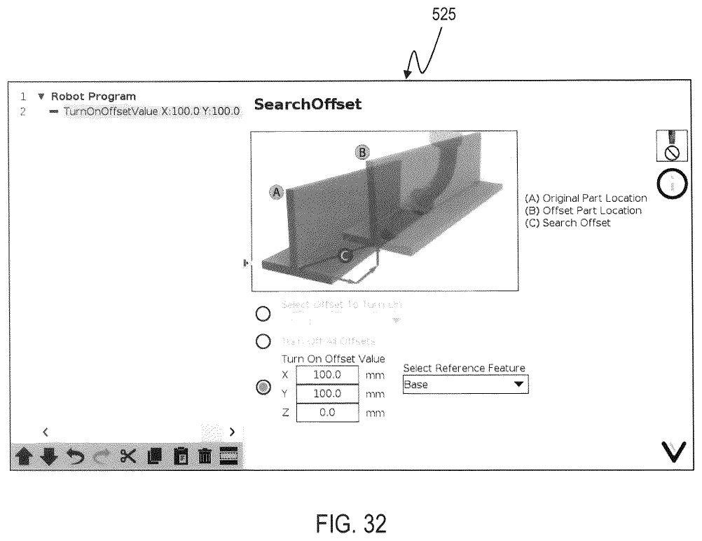

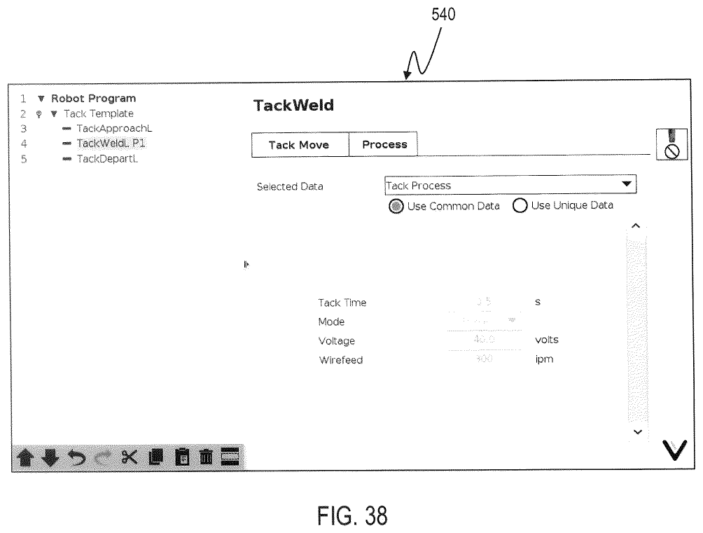

Referring now to FIG. 22, a flow diagram or flow chart presents the process steps of an exemplary welding job cycle. The novel intuitive and graphical programming features and operational methodology for using the welding system are described in FIGS. 23-64 via exemplary screen shots of processing steps and commands as they appear in the application programming interface (API) display 85 of the teach pendant 80 and in supplemental flow diagrams associated therewith. These figures are cross referenced where applicable to the flow chart process steps in the description following. Analogous to setting up a route via waypoints between a start point and a destination using a GPS system, the teach pendant is organized in such a way as to permit an operator or programmer, which designations are used interchangeably herein, to program a job without having an extensive educational background or computer programming or coding training or experience.

First, the operator brings the work materials to be welded to the collaborative robot such as where the system 300 of FIG. 13 is advantageously employed for welding large assemblies. Alternatively, the operator brings the collaborative robot to the work material, as for example, in the situation where welding must be performed in the field and powers on the welding power supply and the collaborative robot. The work material aligned in accordance with the prescribed joint configuration set forth in the associated design drawings and specifications and may be tacked, held in a fixture, or otherwise secured in position. At this point and at any point in the setup and welding process, the operator may select the hand-guided jogging mode as shown in FIGS. 23A and 23B by depressing the programming or hand-guided jog button 92 on the handle of the torch bracket 72. This mode permits free movement and positioning of the welding arm 55 and the torch 70 by the operator. The operator may conveniently engage and disengage the hand-guided jogging mode as needed at any time during the performance of a weld setup and execution procedure. Once the work materials and the robot arm are located relative to one another, the operator may commence the program setup by using the programming button 92 in conjunction with the teach pendant 80 to create a welding path.

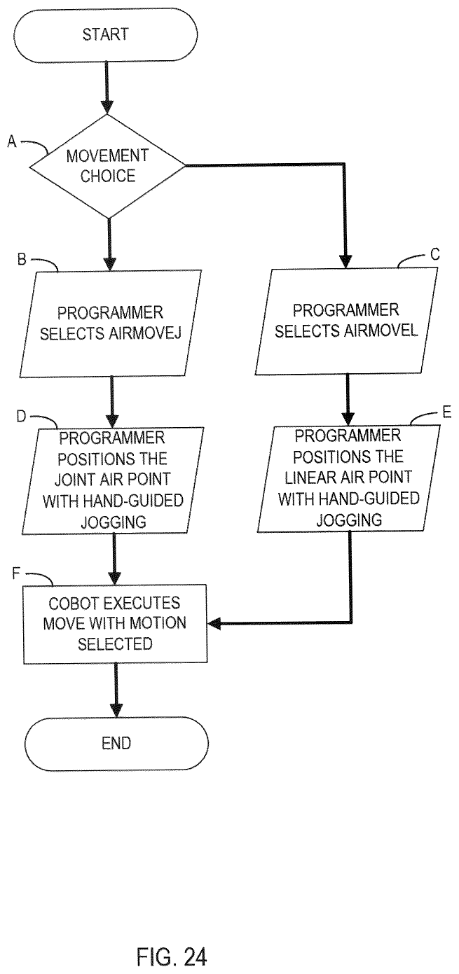

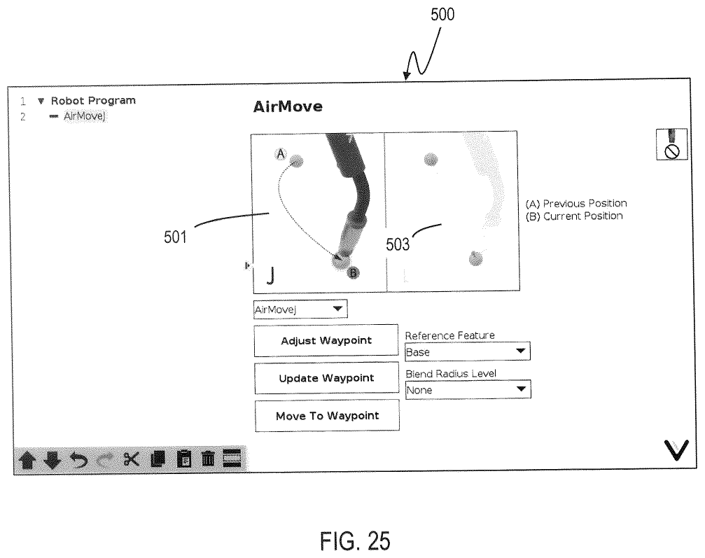

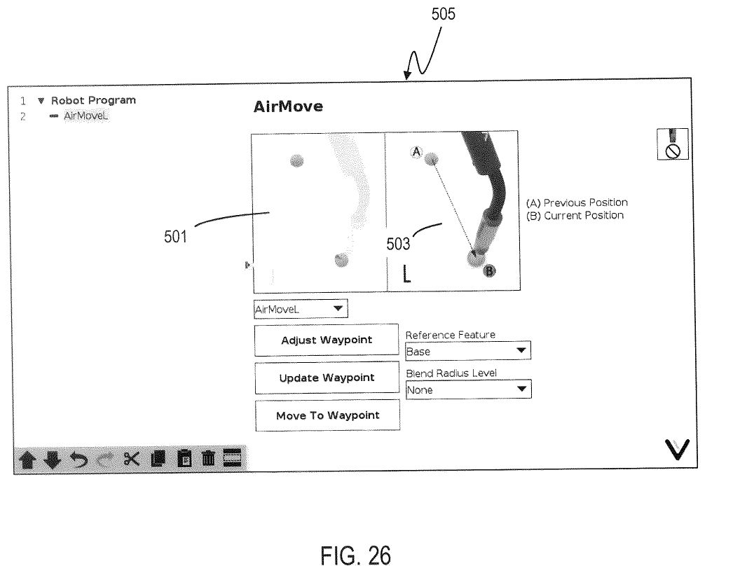

The operator performs a clearance move of the robot arm 55, designated as an AirMove Workflow in step A, FIG. 22 and creates a home position shown as point A on a curved AirMove screenshot 500 and as point A on a linear AirMove screenshot 505 in FIGS. 25 and 26, respectively, to ensure that the robot arm can start from a home or approach position of a weld path indicated generally at 501 and 503 respectively in each of the pictorial presentations. FIG. 24 presents alternate flow diagrams based upon the operator's selection at step A of AirMoveJ for a curved or circular weld path or choice B of AirMoveL for a linear weld path, choice C. An AirMove is a simple move that positions the arm in the working space of the robot. It can be done via a free joint motion (AirMoveJ) where the robot calculates the most optimal movement or in a linear fashion (AirMoveL) where the robot moves directly to a waypoint in a straight line. In either scenario, the operator positions selected waypoints, also referred to herein as airpoints, by moving the robot arm and torch in the hand-guided jogging mode (either step D or step E in FIG. 24) which the robot saves at step F.

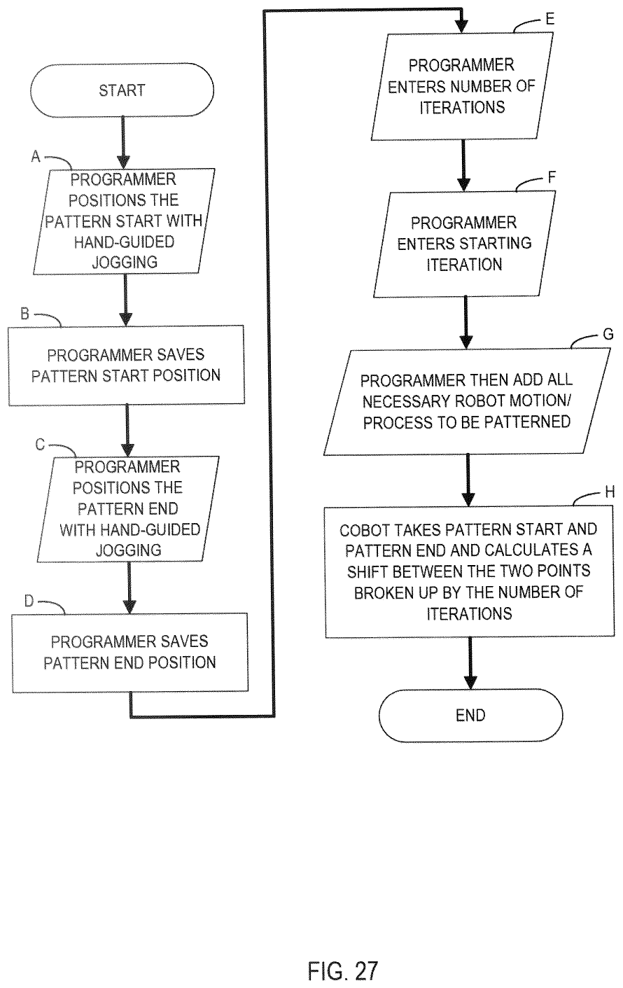

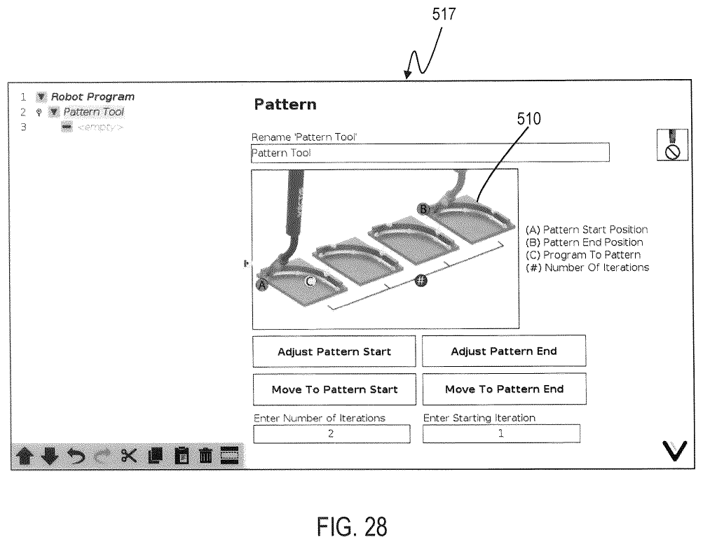

Depending upon the configuration of the weld path, the operator may select a Pattern Workflow subroutine at FIG. 22, step B to establish a weld pattern such as pattern 510 of a circular weld path illustrated in the image of a Pattern screen shot 512 in FIG. 28. The steps of a Pattern Workflow 515 are shown in a flow chart presented in FIG. 27. The operator programs a Pattern Start position (point A in FIG. 28) in hand-guided jogging mode, FIG. 27, step A and saves it in the robot program, step B. The operator then enters hand-guided jogging mode and establishes a Pattern End position (point B in FIG. 28) in step C and saves it, step D. The Pattern Workflow subroutine allows the operator to program a repeatable part that is in a straight line for a number of iterations, which allows a complex program in one area of the working space of the robot to be replicated in a straight line for any number of duplicate setups. This is done by programming a Pattern Start position and a Pattern End position and then entering the number of iterations to be executed, FIG. 27, step E and entering the Starting Iteration, FIG. 27, step F.

At FIG. 27, step G, the programmer defines any number of program nodes and essentially “copies, pastes, translates” that set of program nodes and all necessary robot motions along a defined linear “pattern path” for the defined number of iterations. The Pattern Workflow subroutine is used for quick and uncomplicated programming of a fixture nest of identical parts, for copying a feature's weld path to various positions on a part, or for intermittent tacking. However, the feature only works successfully when the parts to be welded and the positioning fixture for the assembly have very consistent locations and spacing. When the robot executes the program that should be patterned, it calculates a linear shift from the Pattern Start point to the Pattern End point and adjusts the program accordingly by calculating a shift between the two points divided by the number of iterations, FIG. 27, step H.

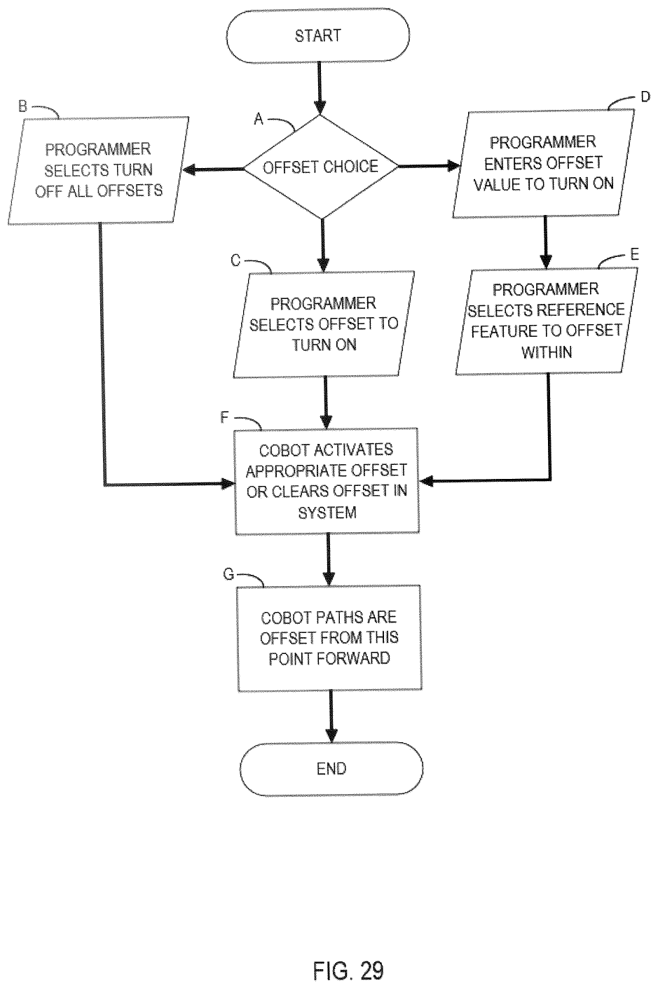

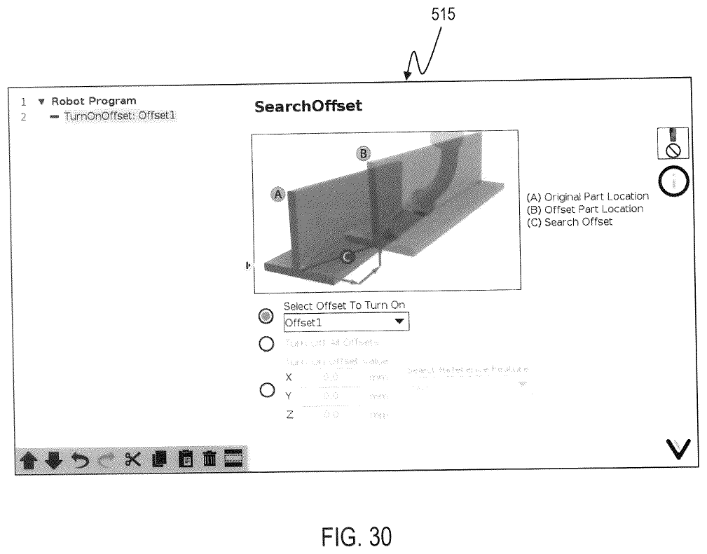

If the work materials are not always in the same position or in a line to use the Pattern Workflow subroutine, at step C, FIG. 22, an operator may use a Search Offset Workflow subroutine which selection allows the operator to manually shift the program in an X, Y, or Z direction by determining and entering required offset values. The relationship between an original part location and an offset part location are shown in screenshot images 515, 520 and 525 in FIGS. 30, 31 and 32, respectively, and the process steps are illustrated in a flowchart presented in FIG. 29.

At FIG. 29, step A, the operator selects either to “Turn Off All Offsets”, step B; or selects which “Offset to Turn On”, step C; or elects to enter an “Offset Value” to manually activate, step D. The reference feature for each offset is selected at step E. The “Turn Off All Offsets” turns off all stored program offsets. The “Select Offset to Turn On” will turn on the offset that is saved for that particular named offset. At step F, the robot either activates the selected offsets or turns off stored offsets in response to the elections made in at the offset choice step, step A. At step G, the path of the collaborative robot during performance of the selected welding program are offset from this point forward.

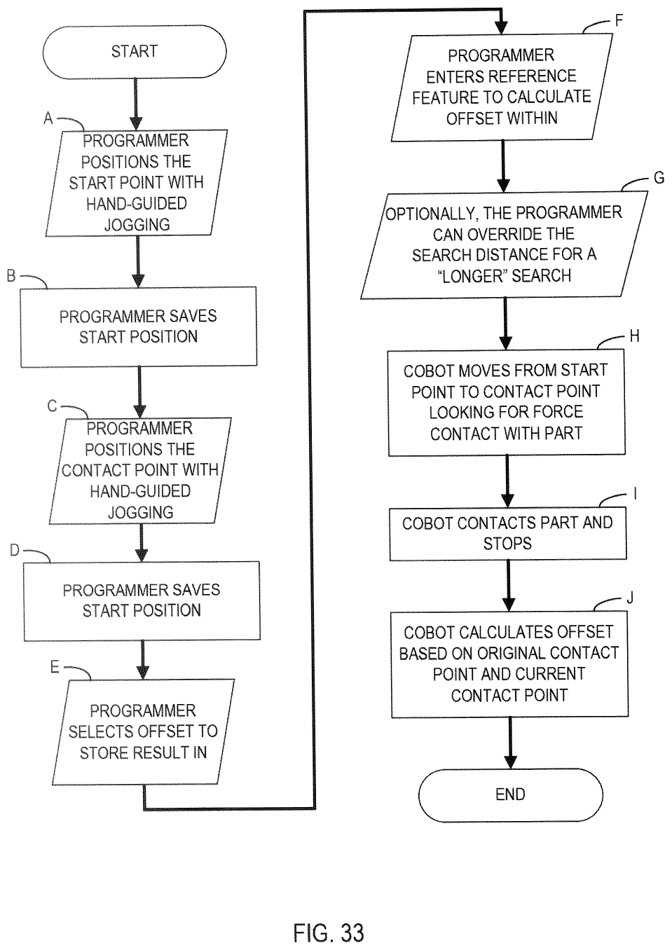

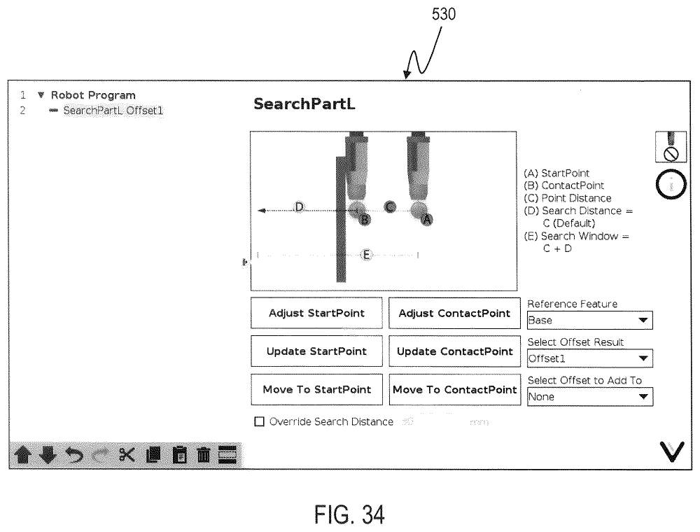

Referring now to step E, FIG. 22, if any of the optional steps B and/or C have been selected, the operator again performs a clearance move of the robot arm 55, the AirMove Workflow defined in step A, FIG. 22 to create a home position. The operator may then select a SearchPartL routine at FIG. 22, step F, the features of which are displayed in screenshot image 530 in FIG. 34. The SearchPart program is used to perform a one-dimensional linear search to identify a program displacement that shifts a program in response to detected positional, rotational or distortional inconsistencies in the work material or unrepeatable part configurations. The SearhPart workflow is shown a flowchart presented in FIG. 33.

To set up the search, the programmer positions the robot via the hand-guided jogging mode and sets a search start point that is not in contact with the part, FIG. 33, step A and saves it in the robot program, step B. The programmer then positions the contact point in hand-guided jogging mode in contact with the work materials to be welded, step C and saves it as a start point, step D, which essentially zero's out the search which would return an offset of 0, had the search been executed. At step E, the programmer then selects the offset name for storage and retrieval of the resultant offset value in the robot program and enters a reference feature upon which an offset may be calculated, step F. An exemplary search distance is shown as D in the screenshot in FIG. 34. Optionally, at step G, the operator may override the search distance and generate a new, longer search distance if deemed necessary. The robot is then ready to execute the search and does so by moving in the programmed search direction and waiting for force feedback or a signal from the process unit that the part has been contacted, step H. Thereafter, the robot stops/halts its motion, step I. Once this contact has occurred, the new contact point is compared to the old contact point and the offset value is calculated and stored in the offset name in the robot program, step J. Additionally, the programmer can choose an offset to start with and “add to” in order to create a compounded two or three-dimensional search.

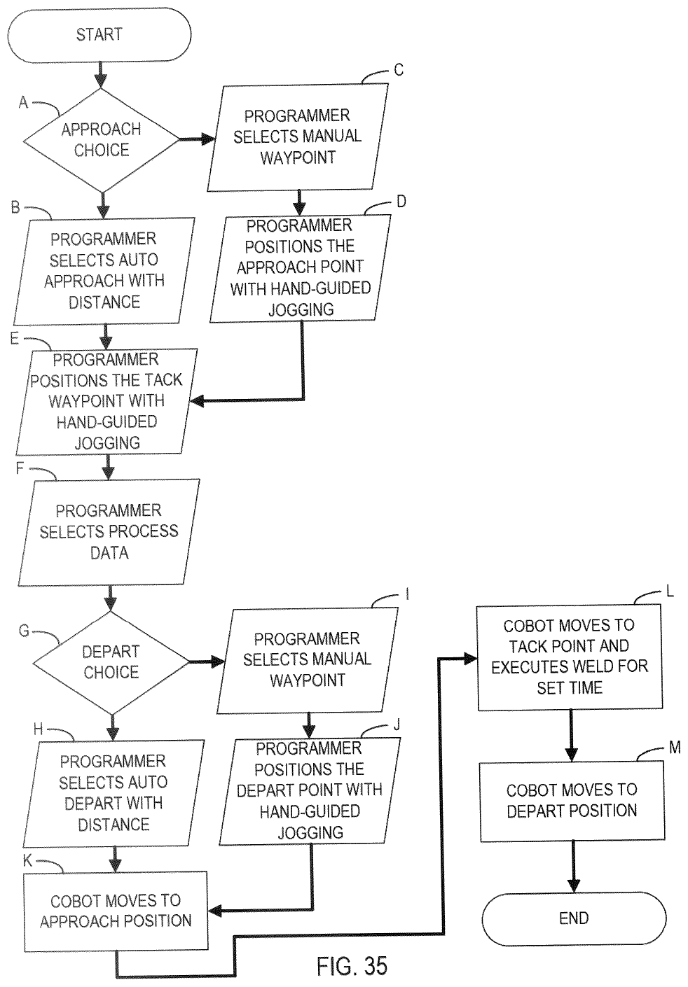

Referring again to FIG. 22, depending upon the weld joint configuration required by a given welding procedure, at this point in the workflow, an operator has several work paths from which to chose to complete the generation of the welds specified in the procedure documents. One option designated “Tack Template Workflow” may be selected at step G, FIG. 22. A Tack Template Workflow flow diagram is shown in FIG. 35. The Tack Template is used to select and assemble an approach point, a tack point, and a depart point for a tack weld, thus ensuring that the robot always move back to a clearance point (approach and depart) to prevent crashing of the system into the work materials. At step A of FIG. 35, the programmer starts by choosing to use an automatically positioned approach point, step B, or programming the waypoint manually, step C. If manual waypoint programming is selected, the programmer then positions the robot at the approach point in hand-guided jogging mode, step D. In either case, the programmer then positions the robot in the hand-guided jogging mode at a selected tack position waypoint, step E and selects the tacking process and time data that will be executed for the tack weld, step F. Finally, at step G, the operator chooses an automatic depart position and distance, step H, or programs this waypoint manually at step I and moves the torch to the depart point hand-guided jogging mode, step J. When the robot executes this template, the robot will move to the approach position at step K, set up all welding monitoring, move to the tacking position and initiate the arc for the specified duration of time, step L. Once the tack weld is complete, the robot will move to the depart position and continue with any remaining program moves, step M.

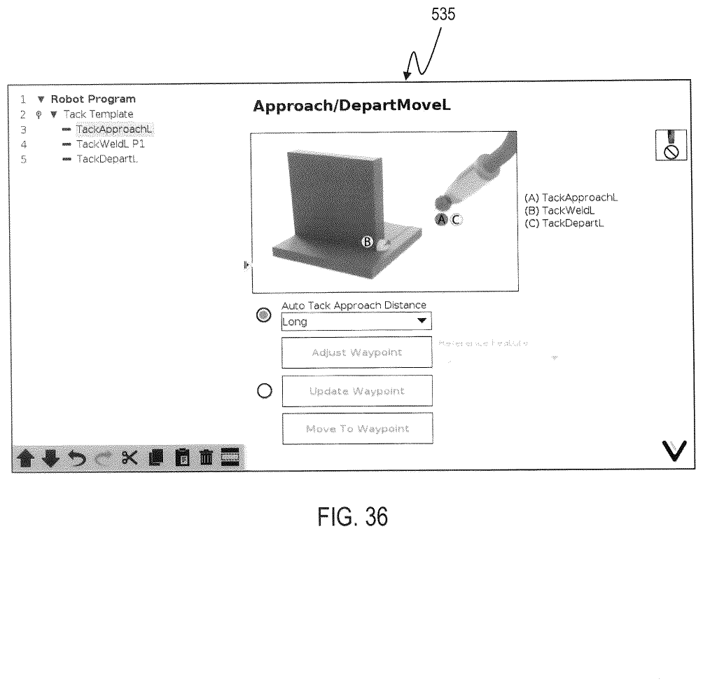

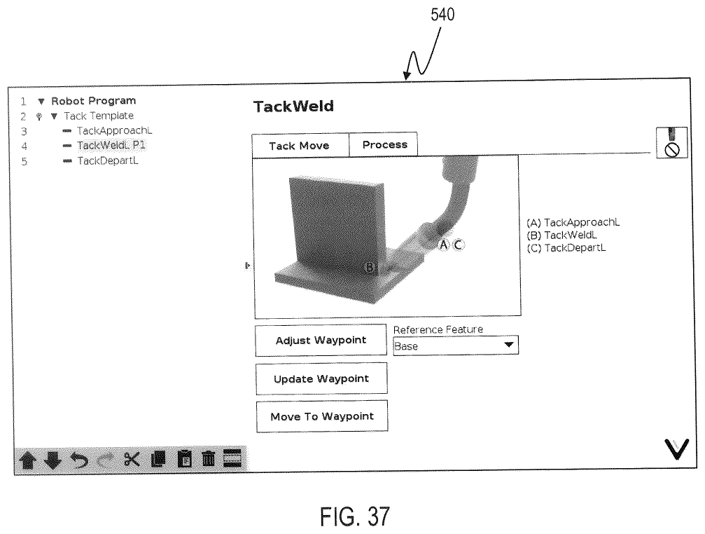

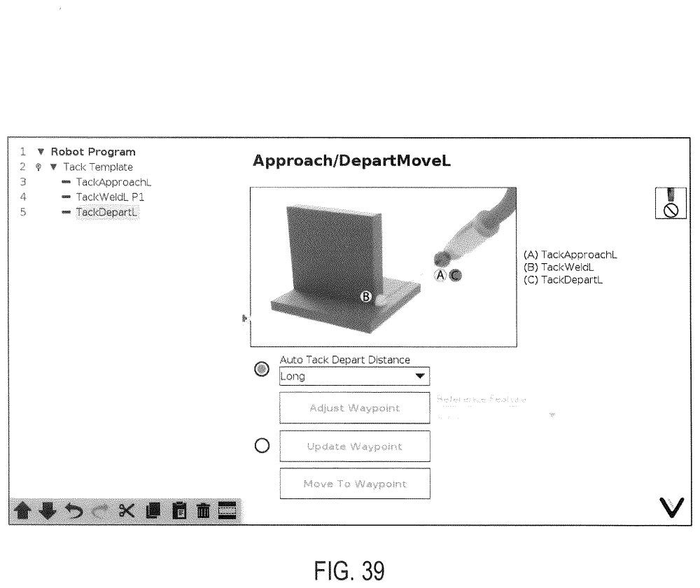

FIG. 36 is a screen shot of the tack approach 535 selected in FIG. 35, step B. FIGS. 36 and 37 are screen shots 540 of the tack weld execution step, step K, FIG. 35, and FIG. 39 is a screen shot of the depart move, step L in FIG. 35.

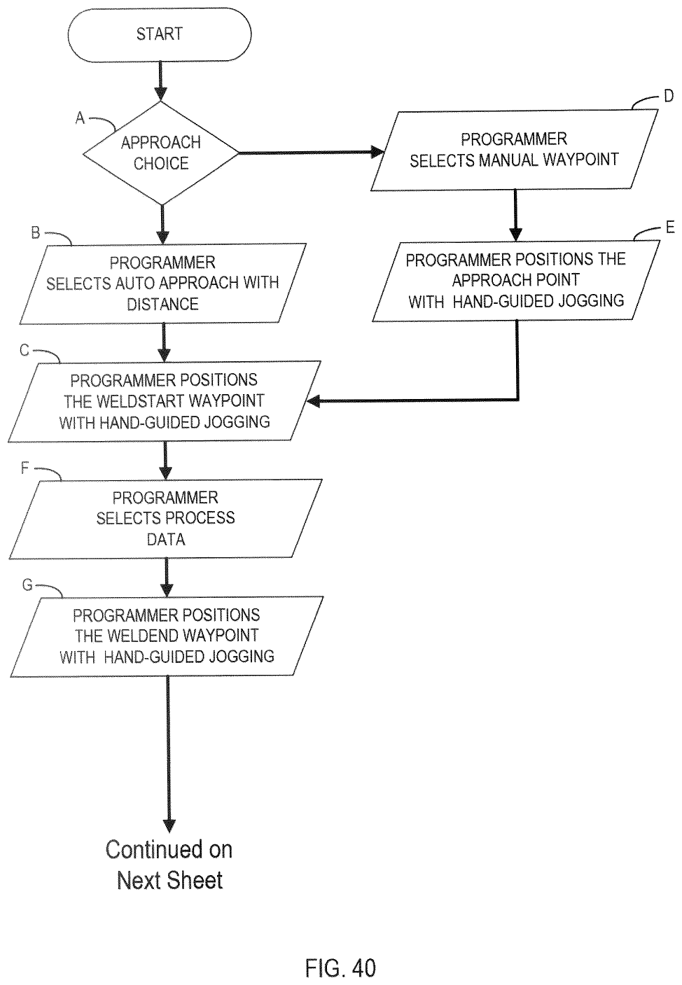

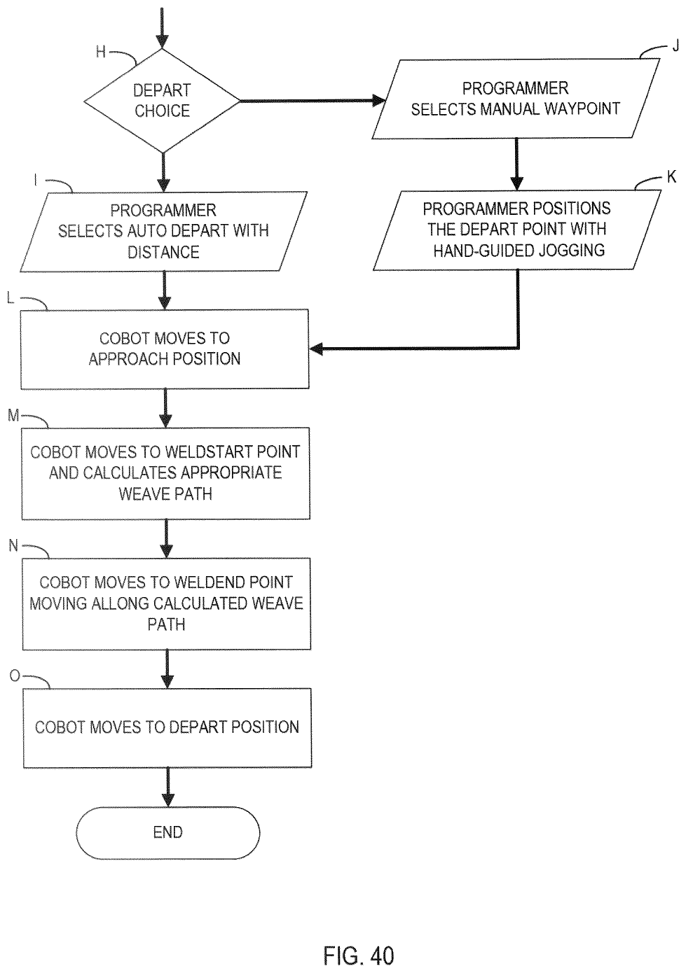

Referring again to FIG. 35, the operator may proceed directly from the home position created in step A to the creation of a Weld Template at step H. The Weld Template workflow is presented in the flow diagram of FIG. 40.

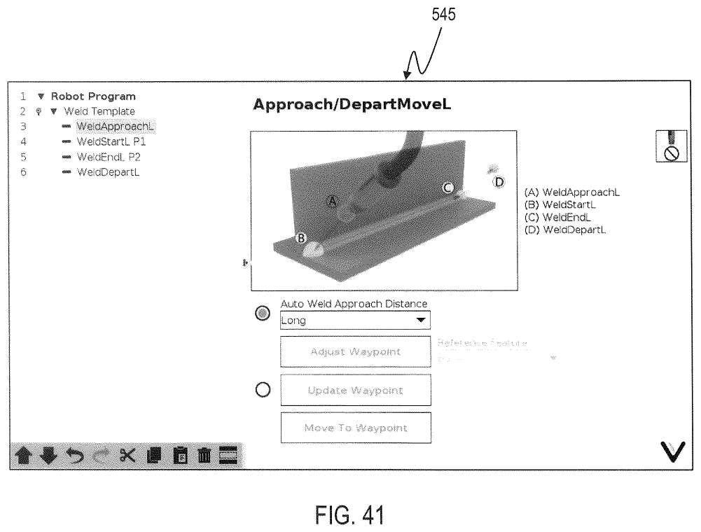

A Weld Template is similar to a Tack Template but gives the programmer the ability to trace out a weld path having three-dimensional shape with any number of segments both linear and circular. Moreover, because the weld path is three dimensional, the robot is capable of oscillating back and forth or weaving to produce a larger weld that fills in more cross-sectional area. A Weld Template is programmed by first choosing to use an automatically positioned approach point or by selecting the waypoint manually similar to a Tack Template. This step is shown at step A in FIG. 40. If an automatically positioned approach is selected, step B, in the next step, step C, the operator selects a “WeldStart” waypoint in hand-guided jogging mode shown as point B in the WeldStart screenshot 545 of FIG. 41 and programs the WeldStart position where the arc will be initiated.

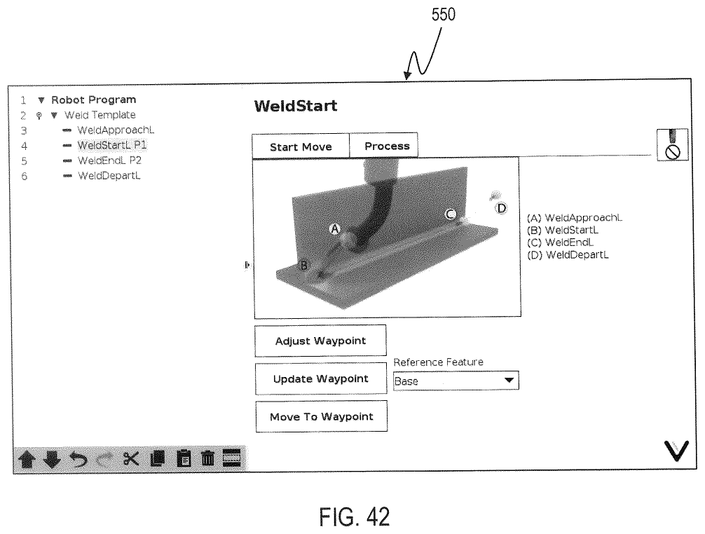

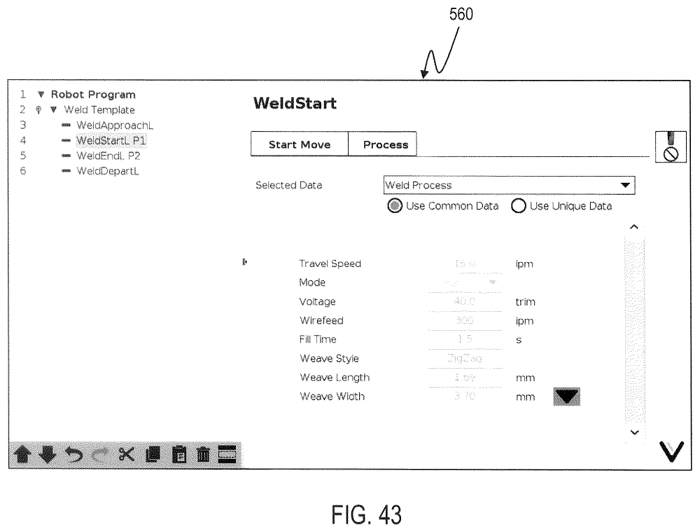

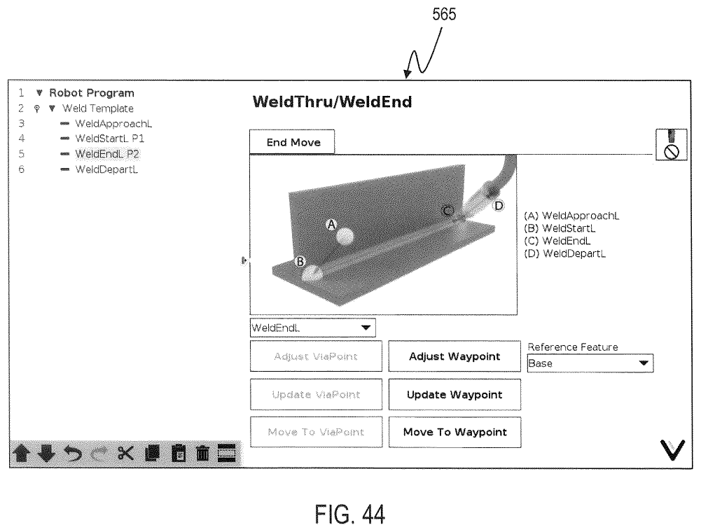

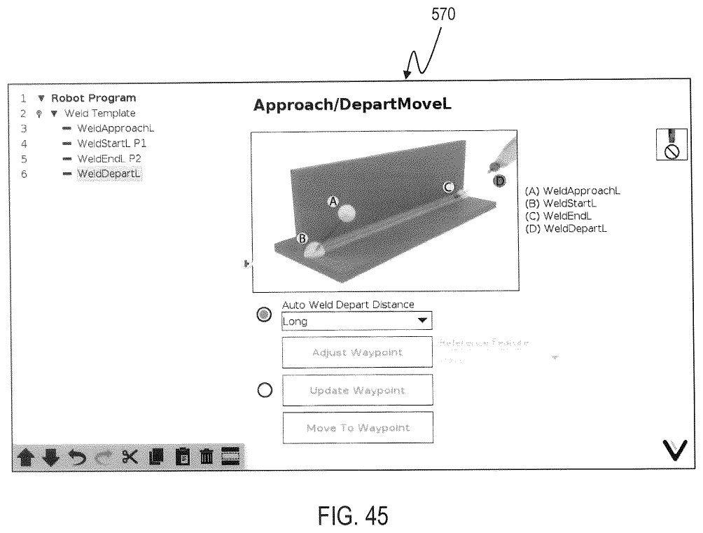

If the operator choses to manually select the WeldStart waypoint, FIG. 40 at step D, he or she will then position an approach point manually in hand-guided jogging mode at step E and thereafter selects a “WeldStart” waypoint in hand-guided jogging mode shown as point A in the WeldStart screenshot 545 of FIG. 42. This step is identical to step C described above with respect to the automatic approach workflow. Next, at FIG. 40, steps F and G, the programmer selects the weld process data and adds in all necessary moves to trace out the weld joint to be welded using any combination of linear and circular WeldThru's or WeldEnd's. These steps are visually shown in screenshots 560 and 565 in FIGS. 43 and 44, respectively. After all the weld points are set at step H, the programmer chooses an automatic depart position, step I or selects a manual depart waypoint in hand-guided jogging mode at step J and programs this waypoint manually at step K, a step similar to the workflow steps described above with respect to the tack template. Once all the weld path positions are set, the programmer goes back to the Weldstart node at step C, chooses the process to be executed while moving along the path from WeldStart to WeldThru or WeldEnd. This process may be a straight path or one that has an oscillation. This process might also be changed at a WeldThru in order to update the process based a change in joint geometry. When the robot executes this template, the robot will move to the approach position, step L, set up all welding monitoring and calculate all necessary oscillation movement, move to the weld start position, and initiate the arc, step M. Once the arc is established, the robot moves with the necessary movement to the WeldThru's or WeldEnd point, step N. Once the weld is complete, the robot will move to the depart position and continue with any remaining program moves, step O. A WeldEnd point is shown as point C and a depart point is shown as point D in screenshot 570 in FIG. 45.

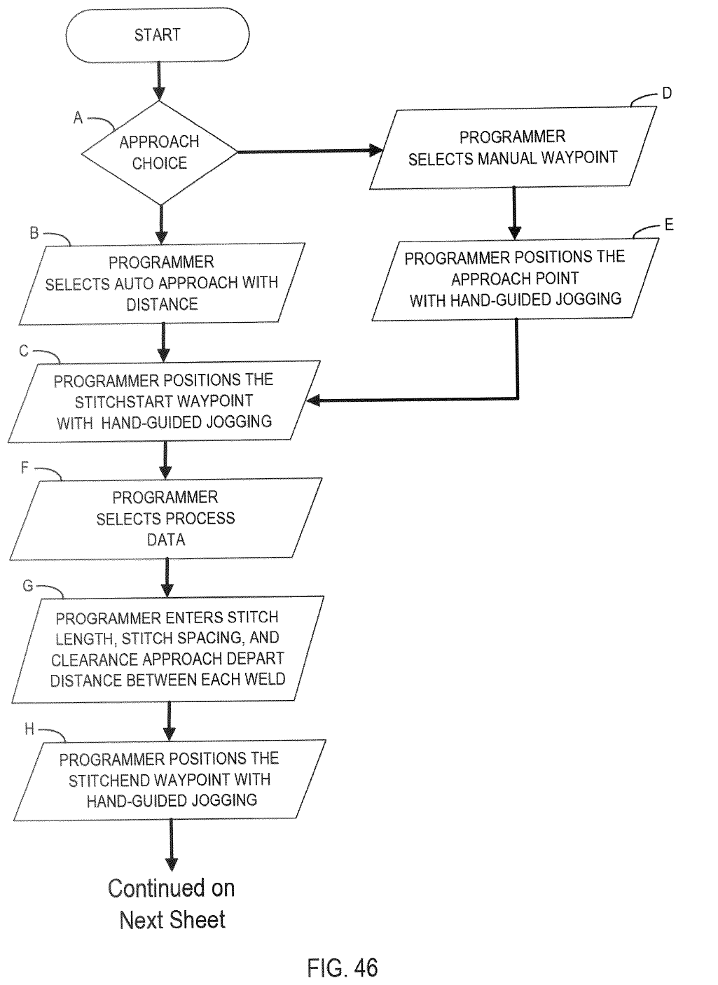

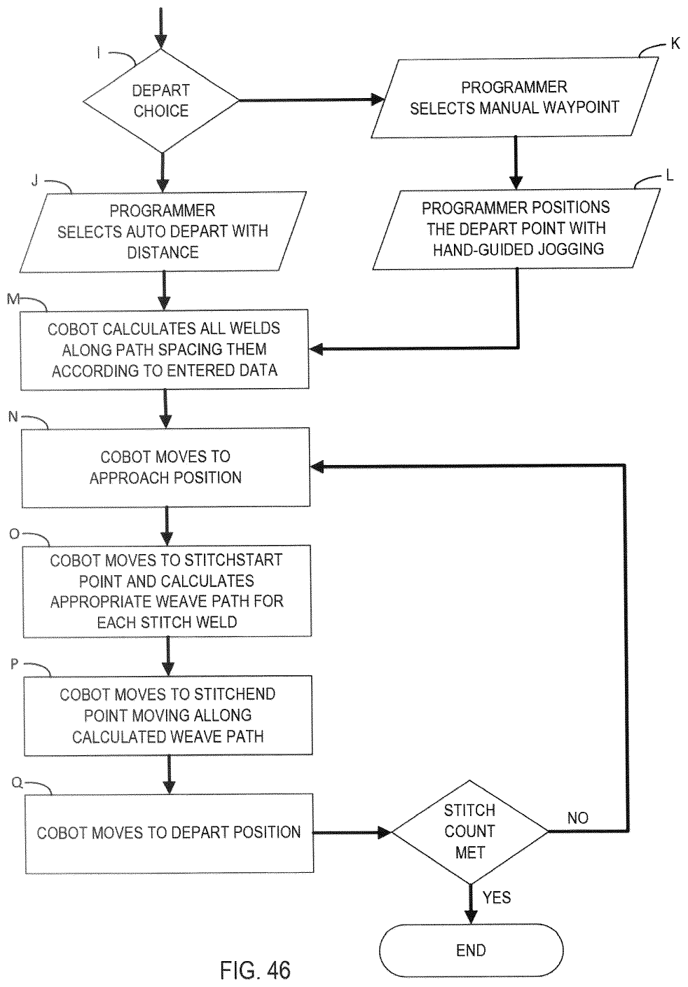

Referring again to the welding workflow flow chart of FIG. 22, an operator may have a weld procedure to execute that requires stitch welding, step I. A stitch template is exactly the same as a weld template except that the weld is not continuous along the length of the path and is instead a much smaller weld that is repeated numerous times down the length of the path and is equally spaced. The path is taught in the exact same way as a normal continuous weld and the only parameters that are new are the stitch weld length and spacing between welds. A stitch template workflow flow diagram is shown in FIG. 46.

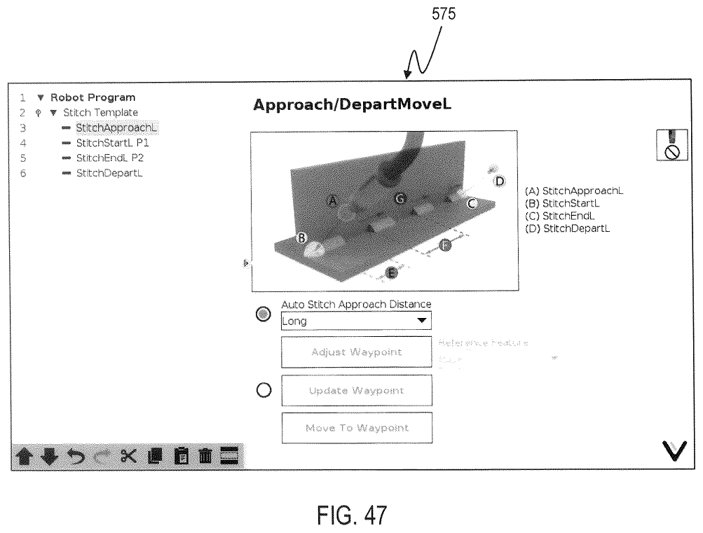

Beginning at step A, a Stitch Template is programmed by first choosing to use an automatically positioned approach point of programming or by selecting the waypoint manually, the same manner in which these steps are performed in programming a Tack or a Weld Template. If an automatically positioned approach is selected, step B, in the next step, step C, the operator then selects a “StitchStart” waypoint in hand-guided jogging mode and programs the start position where the arc will be initiated. StitchStart approach and start points are shown as point A and point B respectively in the Approach/DepartMoveL screenshot 575 of FIG. 47. If the operator choses to manually select the approach waypoint, FIG. 46 at step D, he or she will then position an approach point manually in hand-guided jogging mode at step E and thereafter proceeds to step C described above with respect to the automatic approach workflow. At step F, the operator selects the process data such as stitch length, stitch spacing, clearance approach depart distance between each weld and enters the data into the robot program at step G. He or she positions the robot at a StitchEnd WayPoint using the hand-guided jogging mode at step H, and at step I, selects either an AutoDepart with distance, step J or elects to manually select a depart waypoint, step K. If the manual selection step is chosen, the operator then positions the torch at the depart point manually using the hand-guided jogging mode at step L.

Once these new parameters are added to the weld, the robot is ready to calculate the physical spacing and execute the welds, step M. When the robot executes this template, the robot will move to the approach position, step N, and, at step O, will set up all welding monitoring, calculate all the individual stitch welds along the length of the path, and calculate all necessary oscillation movement or weave path for each stitch weld. The robot then moves to the weld start position and initiates the arc. Once the arc is established, the robot moves with the necessary movement to the end of the individual stitch weld shown at step P. Once the weld is complete, the robot moves to the next stitch weld and repeats the process. Once all stitch welds have been completed, at step Q, the robot will move to the depart position and continue with any remaining program moves. At step R, the robot will verify that the stitch count has been met, and if it has not, the robot will be redirected at step R back to the approach position.

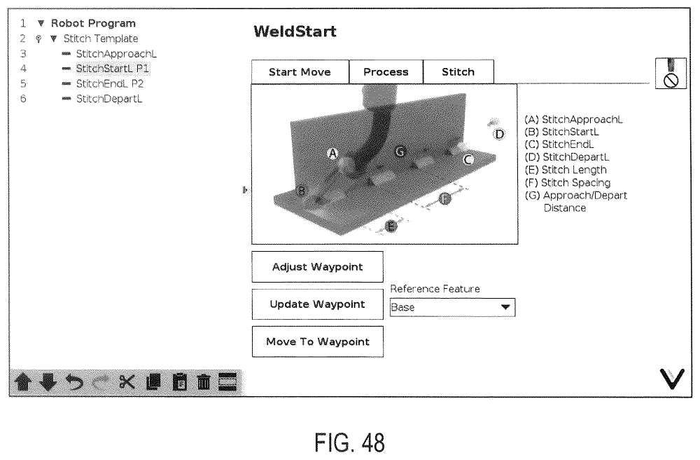

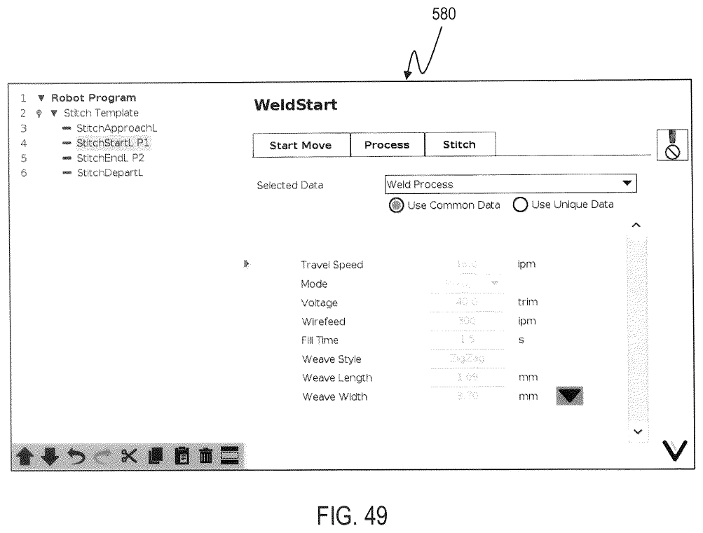

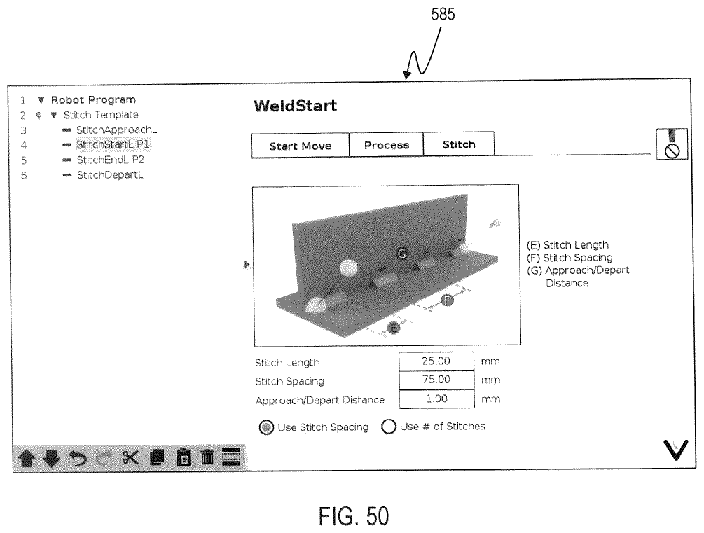

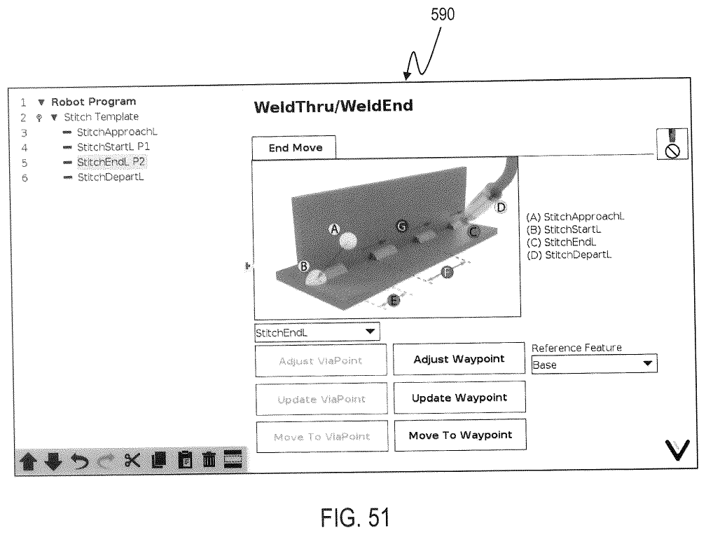

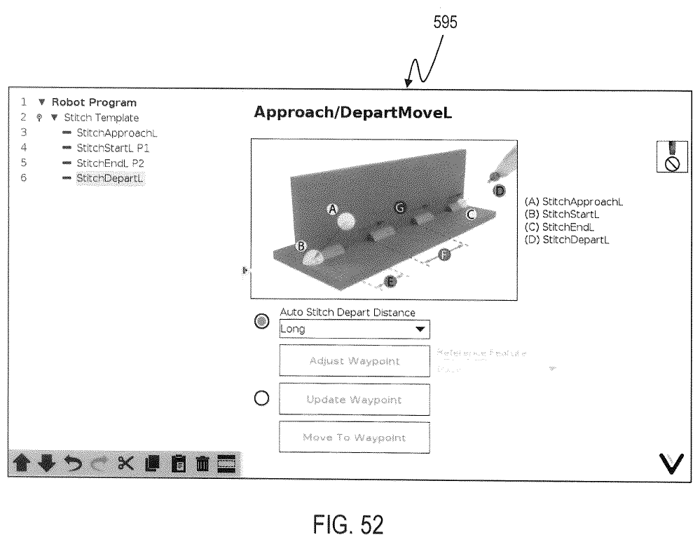

Referring to FIG. 48, the StitchApproach, StitchStart, StitchEnd, StitchDepart, StitchLength, StitchSpacing and ApproachDepart distances are shown in WeldStart screenshot 580 as points A through G, respectively. FIG. 49 illustrates another WeldStart screenshot of a display of weld data such as travel speed, mode (pulse), voltage, wire feed speed and weaving parameters. Weldstart screenshot 585 in FIG. 50 displays start move parameters including stitch length, stitch spacing, and the approach and depart distances, and WeldThru/WeldEnd screenshot 590 in FIG. 51 displays end move parameters such as StitchApproach, StitchStart, StitchEnd and StitchDepart as points A through D, respectively. The StitchDepart point D is shown in the Approach/DepartMoveL screenshot 595 in FIG. 52.

The stitch welding feature of the present invention allows a programmer to define a stitch path and specify stitch parameters to quickly and easily create intermittent welds. The stitch path is taught in the same method as a continuous weld path-always with a Start and an End. Additionally, as will be described in greater detail below, a programmer can add ThruL (linear) and/or ThruC (circular) moves to create a compound path for the stitch weld path.

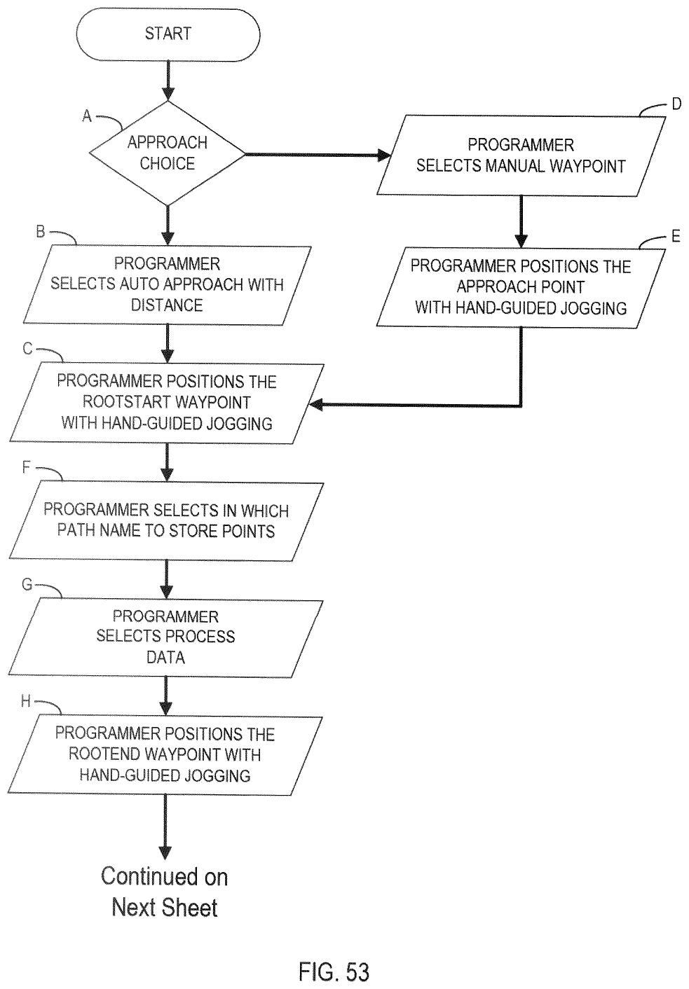

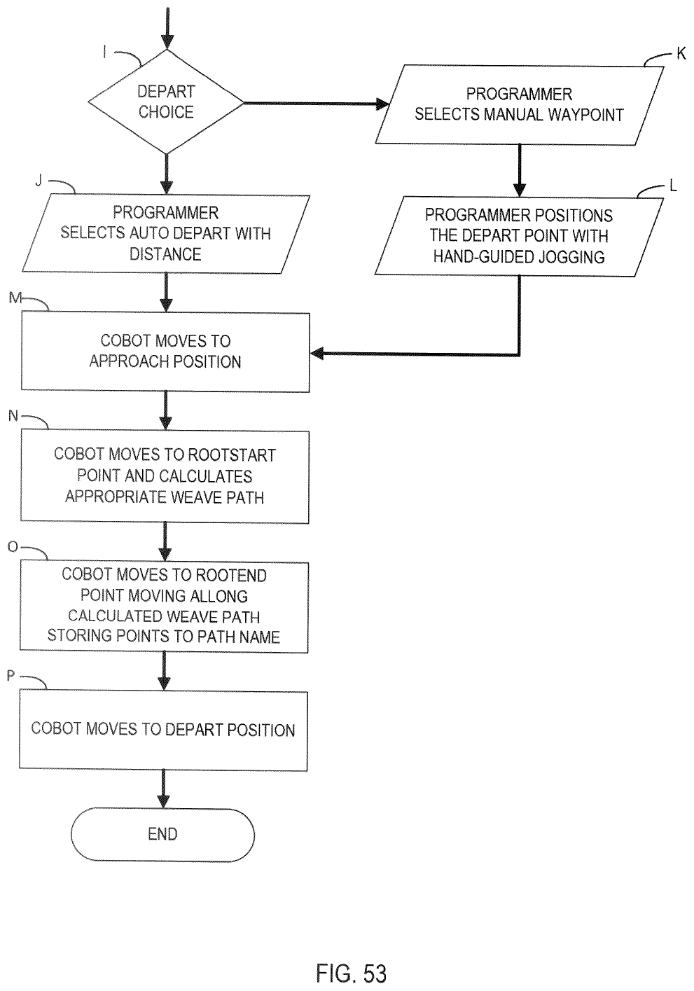

Referring again to FIG. 22, at step J, an operator may elect to create weld moves using a Root Template Workflow, a flowchart of which is presented in FIG. 53. A Root template is exactly the same as a weld template except that the weld path will be saved to a path file that can be called up later in a Replay Template. The path is taught in the exact same way as a normal continuous weld, and the only parameter that is new is the path file name in which to store root template to while executing.

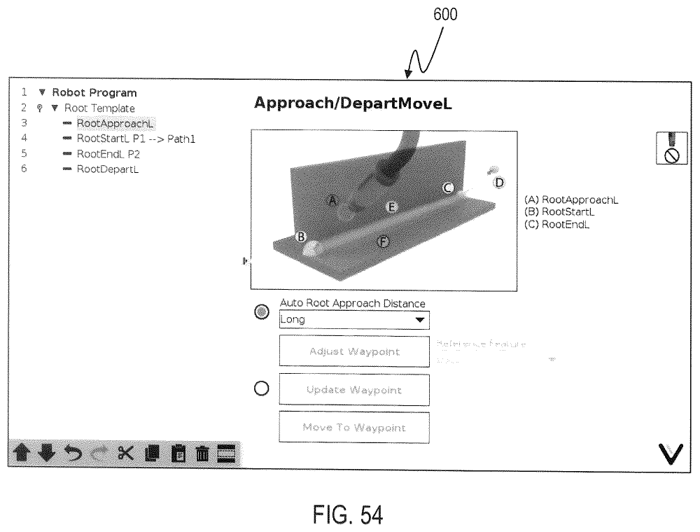

Beginning at step A of FIG. 53, a Root Template is programmed by first choosing to use an automatically positioned approach point of programming or by selecting the waypoint manually, the same manner in which these steps are performed in programming a Tack, Stitch or Weld Template. If an automatically positioned approach is selected, step B, in the next step, step C, the operator then selects a “RootStart” waypoint in hand-guided jogging mode and programs the start position where the arc will be initiated. RootStart approach, start and end points are shown as points A, B and C respectively in the Approach/DepartMoveL screenshot 600 of FIG. 54. If the operator choses to manually select the approach waypoint, FIG. 53 at step D, he or she will then position an approach point manually in hand-guided jogging mode at step E and thereafter proceeds to step C described above with respect to the automatic approach workflow. At step F, the operator selects a path name in which the waypoints are stored and then selects the process data at step G. He or she positions the robot at a RootEnd WayPoint using the hand-guided jogging mode at step H, and at step I, selects either an AutoDepart with distance, step J or elects to manually select a depart waypoint, step K. If the manual selection step is chosen, the operator then positions the torch at the depart point manually using the hand-guided jogging mode at step L.

When the robot executes this template, the robot will move to the approach position at step N, set up all welding monitoring and calculate all necessary oscillation movement, move to the weld start position, and initiate the arc. Once the arc is established, at step O, the robot moves with the necessary movement to the WeldThru's or WeldEnd point saving points along the way to the file specified at step F. Once the weld is complete, the robot will move to the depart position at steep P, process and save all necessary points along the path to replay this path and continue with any remaining program moves.

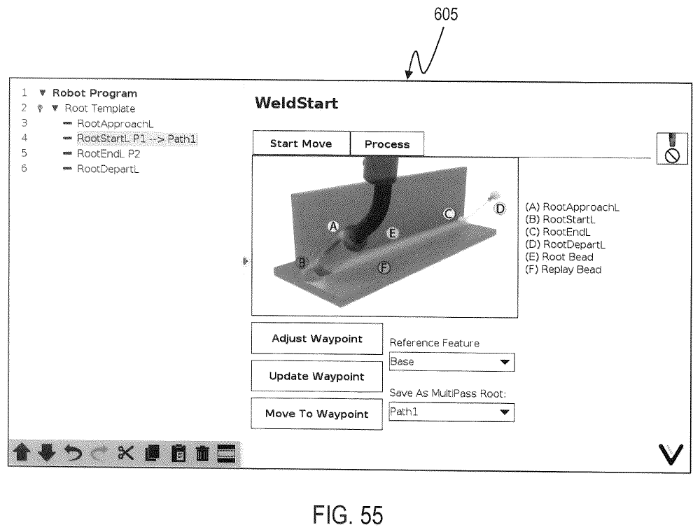

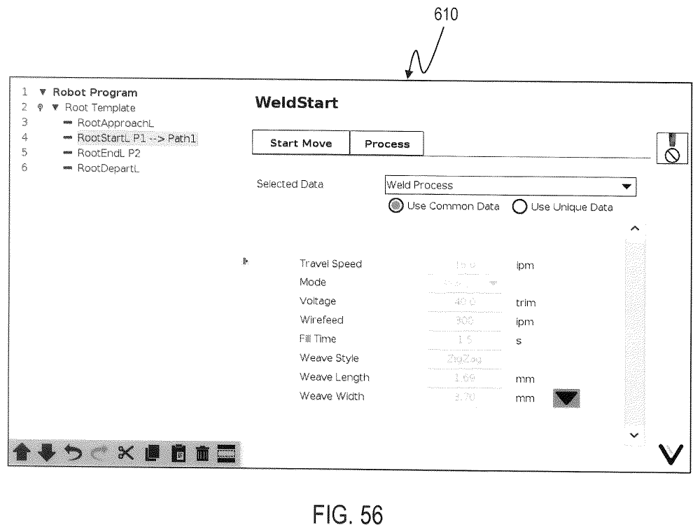

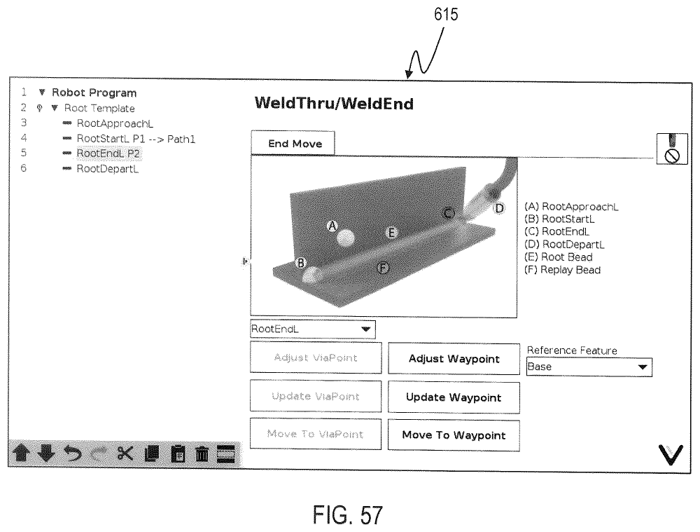

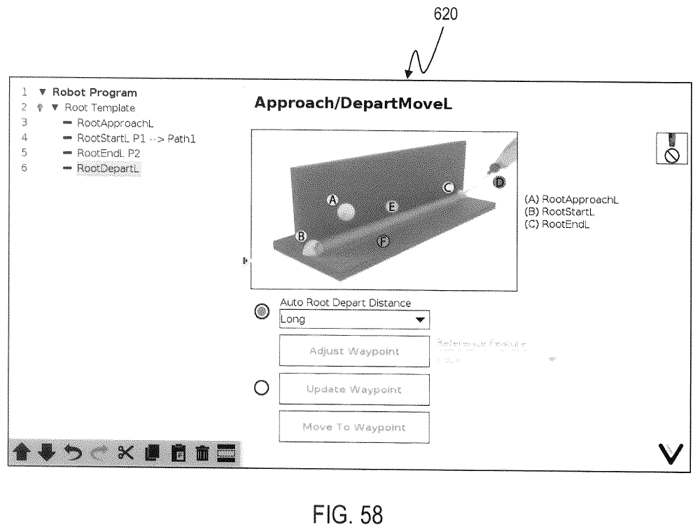

Referring to FIG. 55, the RootApproachL, RootStartL, RootEndL, RootDepartL, Root Bead and Replay Bead points are identified in WeldStart screenshot 605 as points A through F, respectively. FIG. 56 illustrates a Start Move WeldStart screenshot 610 of a display of weld data such as travel speed, mode (pulse), voltage, wire feed speed and weaving parameters. WeldThru/WeldEnd screenshot 615 in FIG. 57 redisplays parameters RootApproachL, RootStartL, RootEndL RootDepartL, Root Bead and Replay Bead points which are identified as points A through F, respectively. The RootDepart point D is shown in the Approach/DepartMoveL screenshot 620 in FIG. 58.

The multi-pass welding feature of the unique control system of the present invention allows a user to seamlessly layer Replay passes which will be described below on top of a Root weld. Any given weld may be saved as a Root path and Replay passes based on a set of “Offset Parameters” may be added. The Replay passes can be numerically entered or automatically calculated from a manual torch placement. This feature can generate several passes over the same weld path without having to re-teach all the waypoints for each new pass.

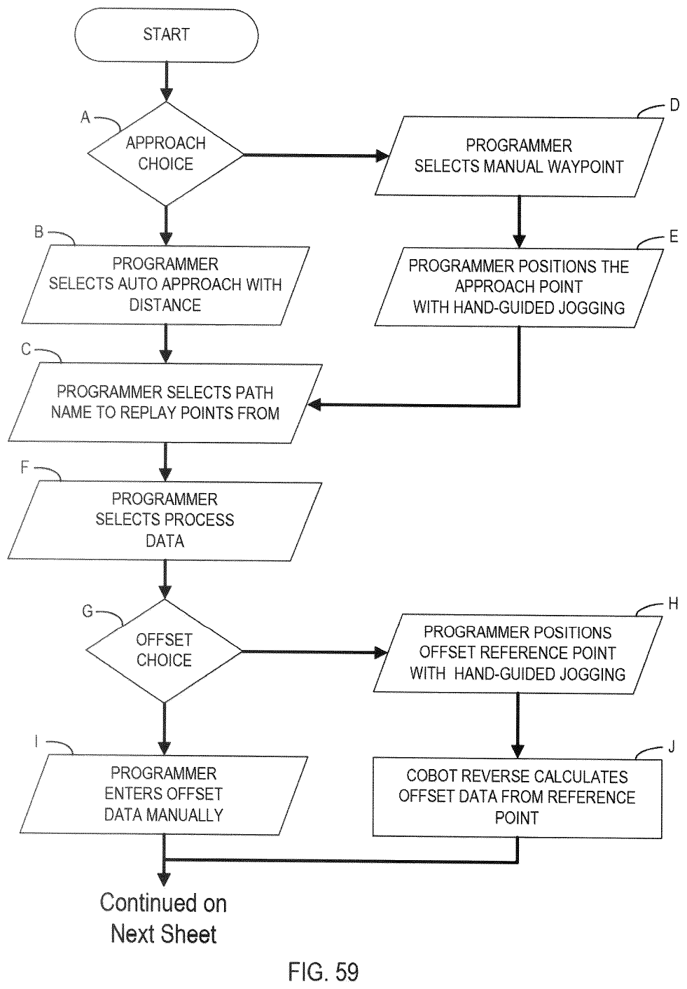

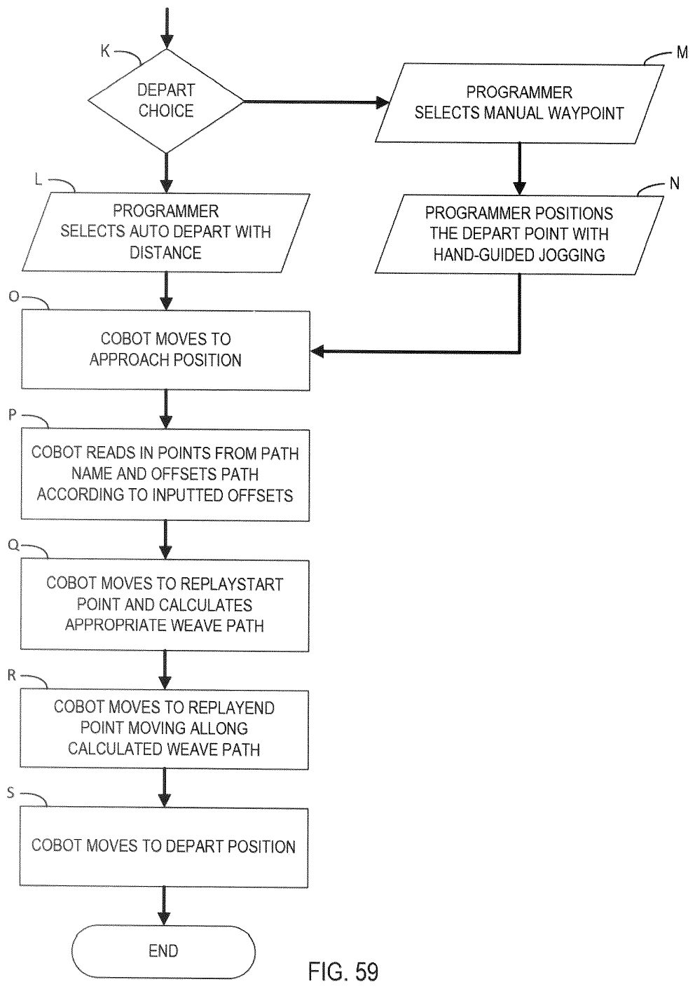

Referring back to FIG. 22, at step K, an operator may elect to create Replay Moves using a Replay Template Workflow, a flowchart of which is presented in FIG. 59. The Replay Template is used to replay the path that was saved via the Root Template. This done by referencing the path file that was created after executing the Root Template and offsetting this path according to an X, Y, and Z path offset as well as a local rotation in the RX, RY, and RZ directions. When the robot executes this template, the robot will move to the approach position, set up all welding monitoring, offsets the root path with the provided multipass offset data, calculates all necessary oscillation movement, moves to the weld start position, and initiates the arc. Once the arc is established, the robot moves with the necessary movement to the saved weld positions. Once the weld is complete, the robot will move to the depart position and continue with any remaining program moves.

The Replay Template Workflow is similar to workflows described earlier with respect to the Tack, Stitch and Root Template Workflows. Beginning at step A of FIG. 59, a Replay Template is programmed by first choosing to use an automatically positioned approach point of programming with distance or by selecting the waypoint manually, the same manner in which these steps are performed in programming a Tack or a Weld Template. If an automatically positioned approach is selected, step B, in the next step, step C, the operator then selects a path name from which the weld path points will be replayed. If the operator choses to manually select the approach waypoint, FIG. 59 at step D, he or she will then position an approach point manually in hand-guided jogging mode at step E and thereafter proceeds to step C described above with respect to the automatic approach workflow. At step F, the operator selects the process data such as voltage, current, wire feed rate and weaving parameters.

At step G, the operator makes an offset choice as to whether to position an offset reference point using the hand-guided jogging mode at step H or, at step I, to enter X, Y, and Z path offset data as well as a local rotation data in the RX, RY, and RZ directions from the path file that was created after executing the Root Template. If step H was selected initially, then at step J, the robot will reverse calculate the offset data from the reference point established in step H.

At step K, the operator selects either an AutoDepart with distance, step L or elects to manually select a depart waypoint, step M. If the manual selection step is chosen, the operator then positions the torch at the depart point manually using the hand-guided jogging mode at step N. After either step L or step N, the robot commences execution of the template and moves to the approach position at step O and, at step P, reads the stored weld path points from the path name file and the offset path points from the stored offset path data. At step Q, the robot moves to the ReplayStart Point, calculates an appropriate weave path and initiates the arc. The robot then moves along the weld path dictated by the stored weld points at step R until it reaches the Depart Position at step S. The MultiPass Welding feature allows Replay passes to be seamlessly layered on top of a Root weld. Any given weld may be saved as a Root path and Replay passes may then be added based on a set of “Offset Parameters” which can be numerically entered or automatically calculated from a manual torch placement. This feature permits the generation of several passes over the same weld path without having to re-teach all the waypoints for each new pass.

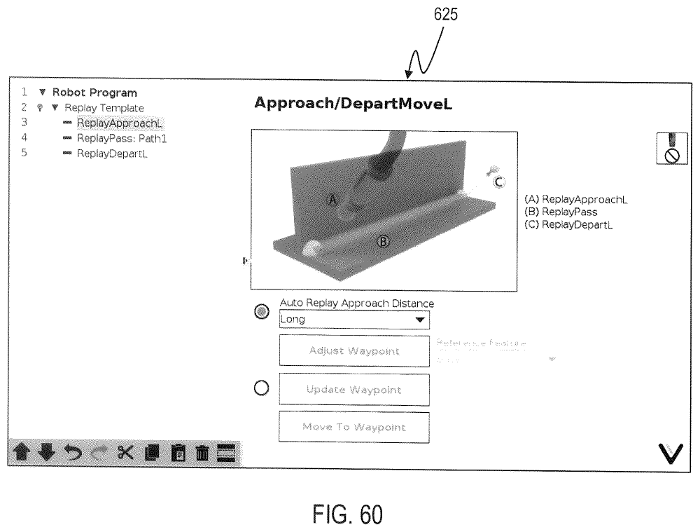

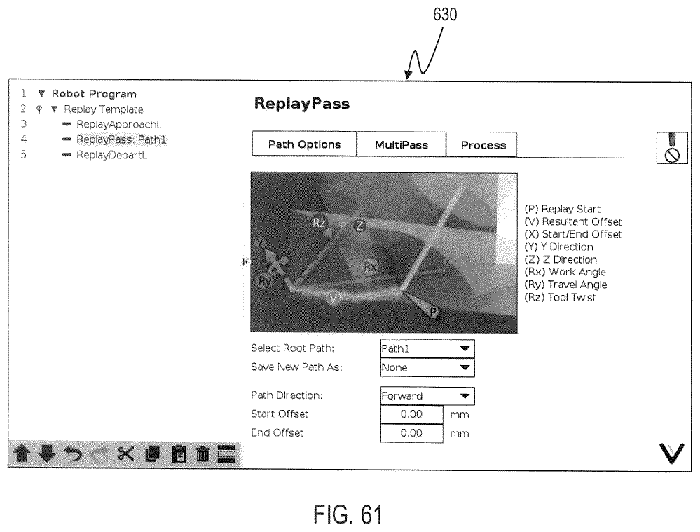

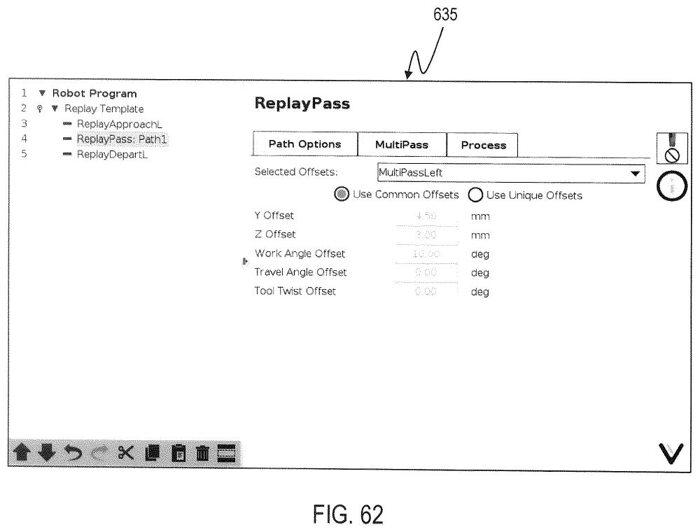

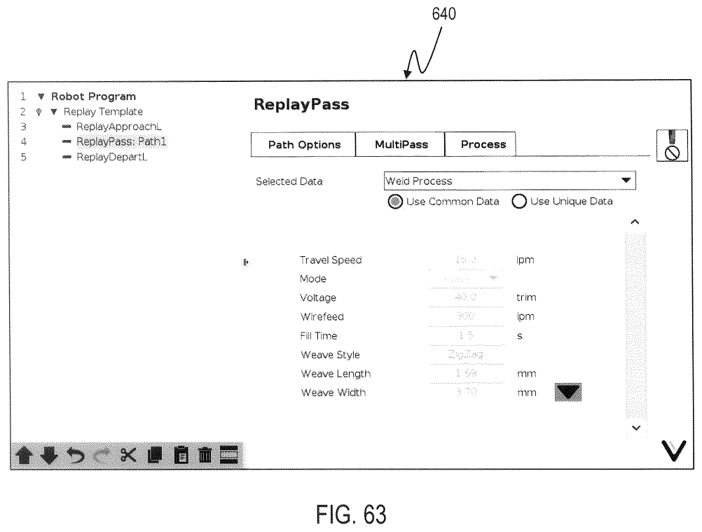

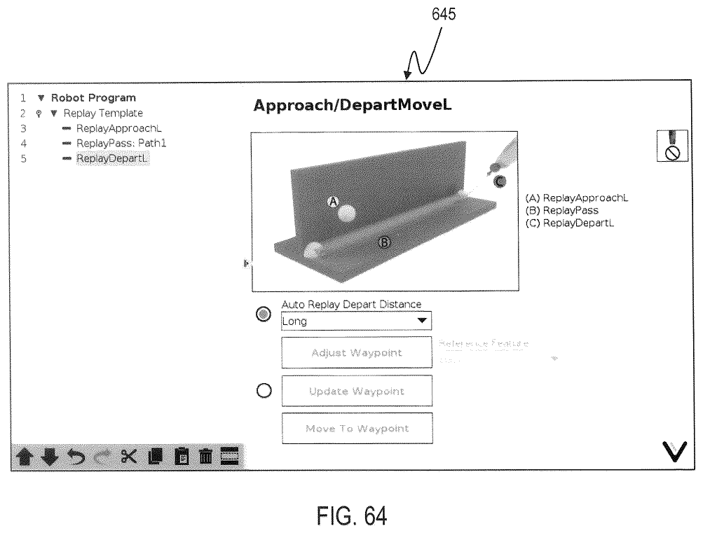

Screenshot 625 in FIG. 60 illustrates a ReplayApproachL at point A, a replay pass at B and a ReplayDepartL at point C. Screenshot 630 in FIG. 61 shows various path option information including Replay Start at point P, a Resultant Offset distance V, a Start/End Offset X, a Y Direction Offset Y, a Z Direction Offset Z, Work Angle Rₓ, Travel Angle R_{y} and a Tool Twist parameter R_{z}. Screenshot 635 in FIG. 62 presents common offset data distances and angles, and screenshot 640 in FIG. 63 includes weld process data such as travel speed, mode (pulse), voltage, wire feed, fill time and weave parameters. Screenshot 645 in FIG. 64 illustrates visually a ReplyApproachL point at A, a ReplayPass at B, and a ReplayDepartL point at C.

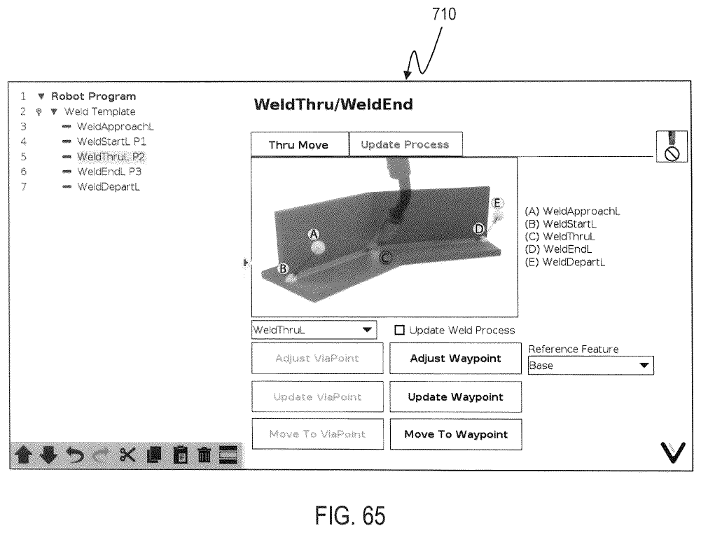

Referring now to FIGS. 65-67, the features of a weld Template 700 are illustrated in screenshots 710, 715 and 720. A Weld Template is similar to a Tack Template but gives the programmer the ability to trace out a three-dimensional shape with any number of segments, both linear and circular. Because the weld path is three dimensional, the robot is capable of oscillating back and forth or weaving to produce a larger weld that fills in more cross-sectional area than if the weld pass was executed without a weave parameter. A Weld Template is programmed by first programming the approach point waypoint manually as described above with respect to programming a Tack Template. Once the approach point is established, the operator programs the WeldStart position, which is the point where the welding arc will be initiated. Next the operator adds in all necessary moves to trace out the specified weld joint using any combination of linear and circular WeldThru or WeldEnd templates such as the exemplary templates shown in screenshots 710, 715 and 720 in FIGS. 65, 66 and 67.

After all the weld points are set, the programmer chooses an automatic depart position or programs a depart position waypoint manually as is done in programming the Tack Template. Once all the weld path positions are set, the programmer returns to the Weldstart node and selects the process to be executed while moving along the path from WeldStart to WeldThru or WeldEnd. By way of example, the selected process may weld a single weld bead having straight path or a weld bead that has an increased cross sectional area generated by employing an oscillation or weaving motion. The process might also be modified in a WeldThru template in response to a change in joint geometry. When the robot executes this template, the robot will move to the approach position, set up all welding monitoring features, calculate oscillation movement, move to the weld start position, and initiate the arc. Once the arc is established, the robot moves with the prescribed movement to the WeldThru or WeldEnd points in accordance with the template parameters stored in the robot program. Once the weld is complete, the robot will move to the depart position and continue with any remaining program moves.

FIG. 65 illustrates an exemplary weld path having two linear segments and displays a WeldApproachL point at A, a WeldStartL point at B, a WeldThruL point at C, a WeldEndL point at D and a WeldDepartL point at E. The letter “L” at the end of the specific point along the weld path signifies that the WeldThru/WeldEnd Template is directed to a linear weld.

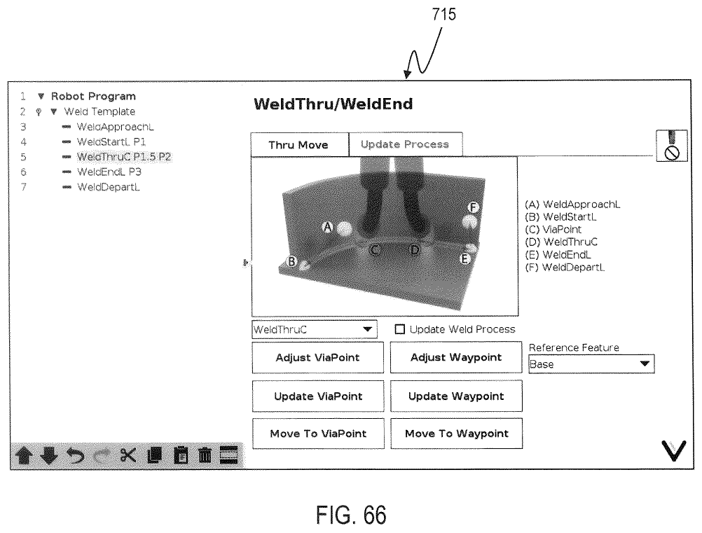

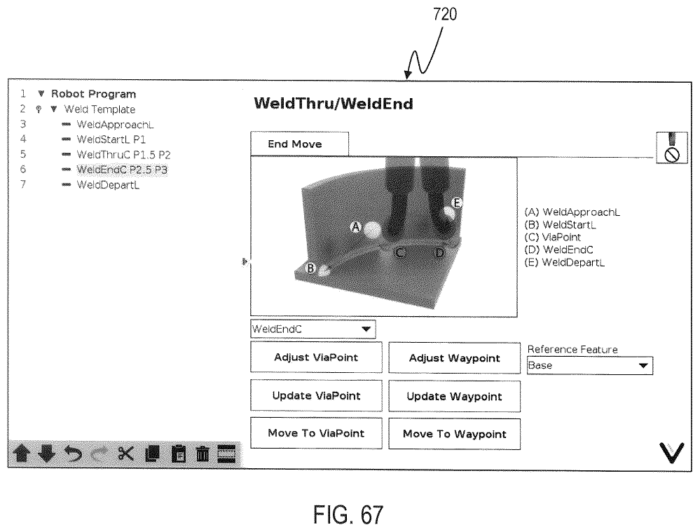

In contrast thereto, screenshot 715 in FIG. 66 illustrates a Thru Move wherein the weld torch orientation changes at ViaPoint C due to the curvature of the weld path between path segment A-C and path segment C-D. Similarly, screenshot 720 in FIG. 67 illustrates an End Move wherein the robot is programmed to end the weld at WeldEndC C and depart at WeldDepartL point E. In both FIGS. 66 and 67, the geometry of the weld path is indicated by the letters “L” or “C” appended to the point descriptor in the control system screenshot.

While only selected embodiments have been chosen to illustrate the present invention, it will be apparent to those skilled in the art from this disclosure that various changes and modifications can be made herein without departing from the scope of the invention as defined in the appended claim. Furthermore, the foregoing descriptions of the embodiments according to the present invention are provided for illustration only, and not for the purpose of limiting the invention as defined by the appended claim and its equivalents.

What is claimed is:

1. A material processing system for performing processing operations on work material, comprising:
a support structure;
a material processing implement;
at least one programmable collaborative robot operatively connected to the support structure and adapted to hold and manipulate the material processing implement;
a power supply operatively connected to the material processing implement;
a control system adapted to enable an operator to guide the programmable collaborative robot and manipulate the material processing implement to operatively engage and process the work material in response to instructions programed by the operator.

2. The material processing system of claim 1 wherein the support structure comprises a mobile base, the mobile base being adapted to be relocated by an operator to bring the material processing system to the work.

3. The material processing system of claim 1 wherein the support structure comprises a stationary base or worktable adapted for use in the fabrication of large assemblies.

4. The material processing system of claim 1 wherein the support structure comprises a mobile base including a bottom or lower platform adapted to stow and transport the power supply and the control system, and an upper cantilevered shelf adapted to mount the programmable collaborative robot, the mobile base being adapted to be relocated by the operator to bring the material processing system to the work.

5. The material processing system of claim 2 wherein the mobile base includes a gridded work surface adapted to receive and secure work material and work holding fixtures thereto.

6. The material processing system of claim 1 wherein the programmable collaborative robot includes a programmable robot arm having a built-in safety mechanism.

7. The material processing system of claim 6 wherein the support structure includes a safety system which permits the collaborative welding system to be operated at a faster speed under predetermined conditions which are safe for an operator and which reduces the system operating speed in accordance with recognized safety standards in response to conditions detected by the safety system.

8. The material processing system of claim 3 further including a boom assembly adapted to selectively move and position one or more programmable collaborative robots on the worktable in response to the size, configuration and number of large assemblies to be processed.

9. The material processing system of claim 1 wherein the material processing implement comprises a welding torch.

10. The material processing system of claim 1 wherein the material processing implement comprises a plasma cutting torch.
